(19) United States
(12) Patent Application Publication
(10) Pub. No.: US 2015/0031216 A1
(43) Pub. Date: Jan. 29, 2015

(54) CLEANING METHOD, METHOD OF MANUFACTURING SEMICONDUCTOR DEVICE, SUBSTRATE PROCESSING APPARATUS, AND RECORDING MEDIUM

(71) Applicant: HITACHI KOKUSAI ELECTRIC, INC., Tokyo (JP)

(72) Inventors: Naonori AKAE, Toyama-shi (JP); Kenji KAMEDA, Toyama-shi (JP)

(73) Assignee: HITACHI KOKUSAI ELECTRIC, INC., Tokyo (JP)

(21) Appl. No.: 14/341,367

(22) Filed: Jul. 25, 2014

(30) Foreign Application Priority Data
Jul. 25, 2013 (JP) 2013-154133

(51) Int. Cl. C23C 16/44; H01L 21/02; C23C 16/52; C23C 16/40; C23C 16/34

(52) U.S. Cl. CPC C23C 16/4405; C23C 16/40; C23C 16/34; C23C 16/52; H01L 21/02164; H01L 21/0217; H01L 21/02263
USPC 438/763; 118/704; 118/697; 134/22.1

(57) ABSTRACT

There is provided a method of cleaning an inside of a process chamber, which is formed by a reaction tube and a manifold configured to support the reaction tube and installed under a heater, after forming a stacked film of oxide and nitride films on a substrate in the process chamber by alternately performing forming the oxide film on the substrate and forming the nitride film thereon. The method includes supplying a hydrogen-free fluorine-based gas from a first nozzle, which is installed in the manifold to extend upward from the manifold to an inside of the reaction tube, to an inner wall of the reaction tube; and supplying a hydrogen fluoride gas from a second nozzle, which is installed in the manifold, to an inner wall of the manifold.

### CROSS-REFERENCE TO RELATED APPLICATION

This application is based upon and claims the benefit of priority from Japanese Patent Application No. 2013-154133, filed on Jul. 25, 2013, the entire contents of which are incorporated herein by reference.

### TECHNICAL FIELD

The present disclosure relates to a cleaning method, which includes a process of cleaning the inside of a process chamber after performing a process of forming a thin film on a substrate, a method of manufacturing a semiconductor device, a substrate processing apparatus and a recording medium.

### BACKGROUND

As one of processes for manufacturing a semiconductor device, there may be a process of forming an insulating film having an Oxide-Nitride-Oxide (ONO) stack structure formed by alternately stacking oxide and nitride films on a substrate. For example, by alternately performing a process of forming a silicon oxide film (SiO film) by supplying a DCS (dichlorosilane, SiH₂Cl₂) gas and a nitrogen dioxide (NO₂) gas into a process chamber having a substrate accommodated therein and a process of forming a silicon nitride film (SiN film) by supplying the DCS gas and an ammonia (NH₃) gas into the process chamber, an insulating film having the ONO stack structure may sequentially be formed on the substrate in the same process chamber.

Although an objective of a thin film forming process is to form a thin film on a substrate, in reality, deposits including the thin film adhere to an inner wall of the process vessel and the like during the thin film forming process. The thickness of the deposits adhering to the process vessel is gradually increased as the deposits are accumulated each time the thin film forming process is performed. If the thickness of such deposits reaches a certain level, a part of the deposits may be peeled off from the inner wall of the process vessel and the like. This may cause foreign substances (particles) to be generated in the process vessel. When the foreign substances are generated within the process vessel and fall on the substrate, it may reduce a product yield rate of the manufacturing process. Therefore, the inside of the process vessel needs to be cleaned by removing any deposits formed thereon whenever the thickness of the deposits reaches a certain level.

Prevailing in the past were wet cleaning methods in which a member such as a reaction tube making up a process vessel is taken out from a substrate processing apparatus and then soaked in a cleaning tank containing an aqueous hydrogen fluoride (HF) solution to remove deposits adhered to the inner wall of the reaction tube. However, in recent years, dry cleaning methods have been widely used, which eliminate the need to take out a reaction tube or the like. In the dry cleaning methods, no operation is required to detach the reaction tube from the substrate processing apparatus. Further, there is no damage to the members making up the reaction tube or the like, which leads to a reduction in costs for maintenance. Moreover, the dry cleaning methods shorten the time until the thin film forming process is resumed. It is possible to expect an improved operating rate of the substrate processing apparatus. For example, as one of the dry cleaning methods, there has been known a method, in which a cleaning gas including a fluorine-containing gas such as a nitrogen trifluoride (NF₃) gas, a fluorine (F₂) gas, or a chlorine trifluoride (ClF₃) gas is thermally activated and supplied into a process vessel.

In the method, in which a cleaning gas including a fluorine-containing gas such as an NF₃ gas, an F₂ gas, or a ClF₃ gas is thermally activated and supplied into a process vessel, when the inside of the process vessel is sufficiently heated, a deposited film can be removed regardless of the kind of the deposited film (an oxide film or a nitride film). However, if there is a portion which may reach a low temperature in the process vessel when the cleaning is performed, since reactivity of the cleaning gas is lowered, a removal rate of the film deposited on the low temperature portion is remarkably decreased. When an insulating film having an ONO stack structure is formed, the present inventors found that since an oxide film is hardly influenced by a film forming temperature, the deposition occurs more frequently even on the low temperature portion. Accordingly, when the cleaning is performed using the thermally activated cleaning gas, there is a problem in that a large amount of residues of the oxide film is present particularly in the low temperature portion. Since the deposits remaining in the process vessel become a factor of generating foreign substances when the thin film forming process is resumed, it is necessary to realize a method by which the cleaning is performed without leaving any deposit residues behind even in the low temperature portion.

### SUMMARY

Accordingly, the present disclosure provides some embodiments of a cleaning method making the removal of deposits on a portion which reaches a high temperature in a process vessel and the removal of deposits on a portion which reaches a low temperature in the process vessel compatible.

According to an aspect of the present disclosure, there is provided a cleaning method for cleaning an inside of a process chamber formed by a reaction tube installed inside a heater and a manifold configured to support the reaction tube and installed under the heater after forming a stacked film of oxide and nitride films on a substrate in the process chamber by alternately performing forming the oxide film and forming the nitride film, the act of forming the oxide film being performed by alternately supplying a first precursor gas to the substrate in the process chamber and supplying an oxygen-containing gas and a hydrogen-containing gas to the substrate in the process chamber under a pressure less than atmospheric pressure once or more, the act of forming the nitride film being performed by alternately supplying a second precursor gas to the substrate in the process chamber and supplying a nitrogen-containing gas to the substrate in the process chamber once or more. The cleaning method includes: supplying a hydrogen-free fluorine-based gas from a first nozzle at least to an inner wall of the reaction tube, the first nozzle being installed in the manifold and raised from the manifold to an inside of the reaction tube; and supplying a hydrogen fluoride gas from a second nozzle at least to an inner wall of the manifold, the second nozzle being installed in the manifold.

According to another aspect of the present disclosure, there is provided a method of manufacturing a semiconductor device, including: forming a stacked film of oxide and nitride films on a substrate in a process chamber formed by a reaction tube installed inside a heater and a manifold configured to support the reaction tube and installed under the heater by alternately performing forming the oxide film and forming the nitride film, the act of forming the oxide film being performed by alternately supplying a first precursor gas to the substrate in the process chamber and supplying an oxygen-containing gas and a hydrogen-containing gas to the substrate in the process chamber under a pressure less than atmospheric pressure once or more, the act of forming the nitride film being performed by alternately supplying a second precursor gas to the substrate in the process chamber and supplying a nitrogen-containing gas to the substrate in the process chamber once or more; and cleaning an inside of the process chamber after the act of forming the stacked film, the act of cleaning the inside of the process chamber, including: supplying a hydrogen-free fluorine-based gas from a first nozzle at least to an inner wall of the reaction tube, the first nozzle being installed in the manifold to extend upward from the manifold to an inside of the reaction tube; and supplying a hydrogen fluoride gas from a second nozzle at least to an inner wall of the manifold, the second nozzle being installed in the manifold.

According to still another aspect of the present disclosure, there is provided a substrate processing apparatus, including: a process chamber formed by a reaction tube installed inside a heater and a manifold configured to support the reaction tube and installed under the heater a gas supply system configured to supply gas into the process chamber; a first nozzle installed in the manifold and raised from the manifold to an inside of the reaction tube; a second nozzle installed in the manifold; a pressure adjusting part configured to adjust an internal pressure of the process chamber; and a control part configured to control the heater, the gas supply system and the pressure adjusting part so as to perform; forming a stacked film of oxide and nitride films on a substrate in the process chamber by alternately performing forming the oxide film and forming the nitride film, the act of forming the oxide film being performed by alternately supplying a first precursor gas to the substrate in the process chamber and supplying an oxygen-containing gas and a hydrogen-containing gas to the substrate in the process chamber under a pressure less than atmospheric pressure once or more, the act of forming the nitride film being performed by alternately supplying a second precursor gas to the substrate in the process chamber and supplying a nitrogen-containing gas to the substrate in the process chamber once or more; and cleaning an inside of the process chamber after the act of forming the stacked film is performed, the act of cleaning the inside of the process chamber including supplying a hydrogen-free fluorine-based gas from the first nozzle at least to an inner wall of the reaction tube, and supplying a hydrogen fluoride gas from the second nozzle at least to an inner wall of the manifold.

According to still another aspect of the present disclosure, there is provided a non-transitory computer-readable recording medium storing a program that causes a computer to perform a process of forming a stacked film of oxide and nitride films on a substrate in a process chamber formed by a reaction tube installed inside a heater and a manifold configured to support the reaction tube and installed under the heater by alternately performing forming the oxide film and forming the nitride film, the act of forming the oxide film being performed by alternately supplying a first precursor gas to the substrate in the process chamber and supplying an oxygen-containing gas and a hydrogen-containing gas to the substrate in the process chamber under a pressure less than atmospheric pressure once or more, the act of forming the nitride film being performed by alternately supplying a second precursor gas to the substrate in the process chamber and supplying a nitrogen-containing gas to the substrate in the process chamber once or more; and a process of cleaning an inside of the process chamber after forming the stacked film, the process of cleaning the inside of the process chamber, including: supplying a hydrogen-free fluorine-based gas from a first nozzle at least to an inner wall of the reaction tube, the first nozzle being installed in the manifold to extend upward from the manifold to an inside of the reaction tube; and supplying a hydrogen fluoride gas from a second nozzle at least to an inner wall of the manifold, the second nozzle being installed in the manifold.

### BRIEF DESCRIPTION OF THE DRAWINGS

FIG. 1 is a schematic view illustrating a configuration of a vertical processing furnace of a substrate processing apparatus, in which a portion of the processing furnace is shown in a longitudinal sectional view, according to some embodiments of the present disclosure.

FIG. 2 is a schematic view illustrating a configuration of the vertical processing furnace of the substrate processing apparatus, in which a portion of the processing furnace is shown in a sectional view taken along line A-A in FIG. 1, according to some embodiments of the present disclosure

FIG. 3 is a schematic view illustrating a configuration of a controller of the substrate processing apparatus according to some embodiments of the present disclosure.

FIG. 4 is a view illustrating a flow of film formation according to one embodiment of the present disclosure.

FIG. 5 is a view illustrating supply timings of precursor gases and the like according to the embodiment of the present disclosure.

FIG. 6 is a view illustrating supply timings of cleaning gases and the like according to the embodiment of the present disclosure.

FIG. 7 is a view illustrating a first modification of the supply timings of the cleaning gases according to the embodiment of the present disclosure.

FIG. 8 is a view illustrating a second modification of the supply timings of the cleaning gases according to the embodiment of the present disclosure.

FIG. 9 is a view illustrating a third modification of the supply timings of the cleaning gases according to the embodiment of the present disclosure.

FIG. 10 is a view illustrating a fourth modification of the supply timings of the cleaning gases according to the embodiment of the present disclosure.

FIG. 11 is a view illustrating a fifth modification of the supply timings of the cleaning gases according to the embodiment of the present disclosure.

FIG. 12 is a view illustrating a sixth modification of the supply timings of the cleaning gases according to the embodiment of the present disclosure.

FIG. 13 is a view illustrating a seventh modification of the supply timings of the cleaning gases according to the embodiment of the present disclosure.

FIG. 14 is a view illustrating an eighth modification of the supply timings of the cleaning gases according to the embodiment of the present disclosure

FIG. 15A is a view illustrating a configuration of a nozzle according to the embodiment of the present disclosure, FIG. 15B is a view illustrating a nozzle according to a ninth modification, FIG. 15C is a view illustrating a nozzle according to a tenth modification, FIG. 15D is a view illustrating a nozzle according to an eleventh modification, FIG. 15E is a view illustrating a nozzle according to a twelfth modification, and FIG. 15F is a view illustrating a nozzle according to a thirteenth modification.

FIG. 16A is a graph showing dependence of an oxide film forming rate and an oxide film removal rate by a ClF₃ gas on a position in a reaction tube, and FIG. 16B is a graph showing dependence of a nitride film forming rate and a nitride film removal rate by the ClF₃ gas on a position in the reaction tube.

FIG. 17A is a graph showing dependence of an oxide film removal rate on a cleaning gas species, and FIG. 17B is a graph showing dependence of a nitride film removal rate on a cleaning gas species.

### DETAILED DESCRIPTION

Hereinafter, embodiments of the present disclosure will be described with reference to the drawings.

### Embodiment of the Present Disclosure

### (1) Configuration of Substrate Processing Apparatus

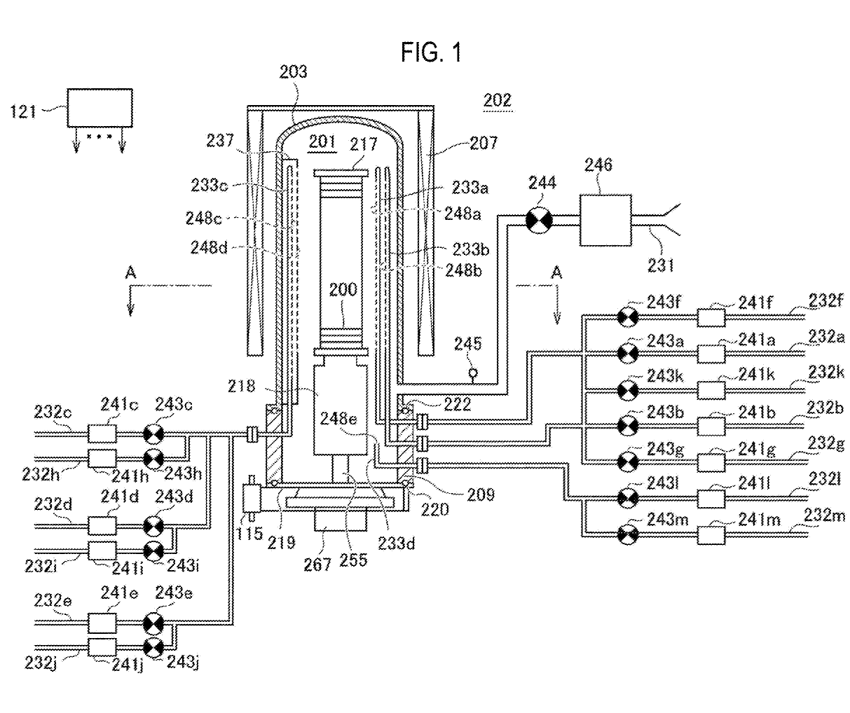

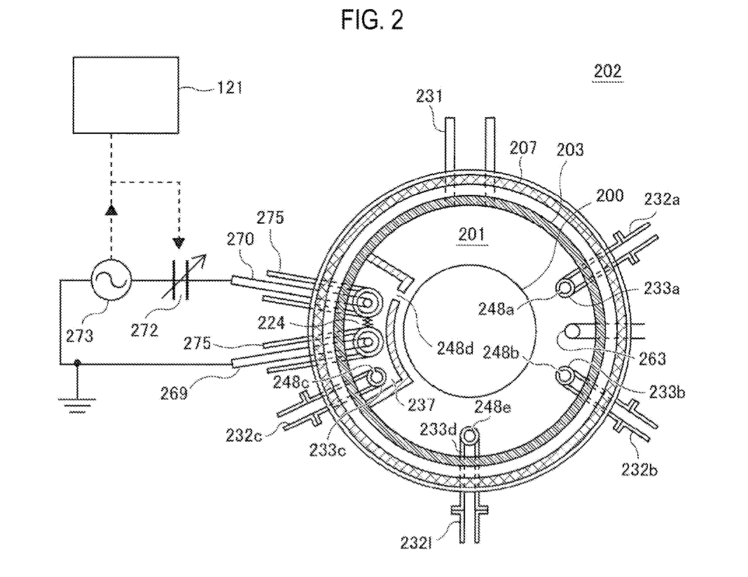

As shown in FIGS. 1 and 2, a processing furnace 202 includes a heater 207 as a heating unit (heating mechanism). The heater 207 has a cylindrical shape and is supported by a heater base (not shown) as a support plate so as to be vertically installed. In addition, the heater 207 acts as an activating mechanism configured to activate gas by heat, as described later.

A reaction tube 203 defining a reaction vessel (process vessel) is disposed inside the heater 207 in a concentric form along the heater 207. The reaction tube 203 is made of a heat resistant material such as quartz (SiO₂) or silicon carbide (SiC), and has a cylindrical shape with its upper end closed and its lower end opened. A process chamber 201 is provided in a hollow cylindrical portion of the reaction tube 203 and a manifold 209 described later and is configured to accommodate a plurality of wafers 200, which are horizontally stacked in multiple stages to be aligned in a vertical direction in a boat 217 described later.

The manifold 209 is installed under the reaction tube 203. More specifically, the manifold 209 is disposed so that at least its upper end is positioned under a lower end of the reaction tube 203 and a lower end of the heater 207. The manifold 209 is made of, e.g., metal, and supports the reaction tube 203. An O-ring 222 as a sealing member in contact with the lower end of the reaction tube 203 is installed on an upper surface of the manifold 209.

A nozzle 233a used as a first nozzle configured to supply a hydrogen-free fluorine-based gas and used as a first gas introduction portion, a nozzle 233b used as the first nozzle configured to supply the hydrogen-free fluorine-based gas in the same manner and used as a second gas introduction portion, a nozzle 233c as a third gas introduction portion, and a nozzle 233d used as a second nozzle configured to supply a hydrogen fluoride (HF) gas are installed in the process chamber 201 so that they penetrate through a sidewall of the manifold 209. A gas supply pipe 232a and a gas supply pipe 232k are connected to the nozzle 233a. In addition, a gas supply pipe 232b and the gas supply pipe 232k are connected to the nozzle 233b. Further, a gas supply pipe 232c, a gas supply pipe 232d and a gas supply pipe 232e are connected to the nozzle 233c. Furthermore, a gas supply pipe 232l is connected to the nozzle 233d. In this way, the four nozzles 233a, 233b, 233c and 233d and the seven gas supply pipes 232a, 232b, 232c, 232d, 232e, 232k and 232l are installed in the manifold 209, and thus, a plurality of gases (seven in this example) may be supplied into the process chamber 201.

Mass flow controllers (MFCs) 241a to 241e, which are flow rate controllers (flow rate control part), and valves 243a to 243e, which are opening/closing valves, are installed in the gas supply pipes 232a to 232e in this order from an upstream direction, respectively. In addition, inert gas supply pipes 232f to 232j are connected to the gas supply pipes 232a to 232e at downstream sides of the valves 243a to 243e, respectively. MFCs 241f to 241j and valves 243f to 243j, which are opening/closing valves, are installed at the inert gas supply pipes 232f to 232j in this order from an upstream direction, respectively. In addition, the above-described nozzles 233a to 233c are connected to leading ends of the gas supply pipes 232a to 232c, respectively.

Each of the nozzles 233a and 233b is installed in an annular space between the inner wall of the reaction tube 203 and the wafers 200 so as to extend upward along the inner wall of the manifold 209 and a lower portion of the inner wall of the reaction tube 203 in the stacking direction of the wafers 200. That is, each of the nozzles 233a and 233b is installed at the side of the wafer arrangement region, in which the wafers 200 are arranged, so as to rise from the manifold 209 to the inside of the reaction tube 203. Each of the nozzles 233a and 233b is configured as an L-shaped long nozzle and has its horizontal portion installed to penetrate through the sidewall of the manifold 209 and its vertical portion installed to rise at least from one end of the wafer arrangement region toward the other end thereof. Gas supply holes 248a and 248b through which gases are supplied are respectively formed in side surfaces of the nozzles 233a and 233b. The gas supply holes 248a and 248b are opened toward the center of the reaction tube 203 to enable gases to be supplied toward the wafers 200. The gas supply holes 248a or 248b are disposed at the same opening pitch from the lower portion to the upper portion of the reaction tube 203 and have the same opening area.

The nozzle 233c is installed inside a buffer chamber 237 that is a gas diffusion space. The buffer chamber 237 is installed in an annular space between the inner wall of the reaction tube 203 and the wafers 200. The buffer chamber 237 is vertically disposed along the inner wall of the reaction tube 203 in the stacking direction of the wafers 2(K). That is, the buffer chamber 237 is installed at the side of the wafer arrangement region, in which the wafers 200 are arranged. A plurality of gas supply holes 248d through which gas is supplied is formed in an end of a wall of the buffer chamber 237 adjacent to the wafers 200. The gas supply holes 248d are opened toward the center of the reaction tube 203 to supply gas toward the wafers 200. The gas supply holes 248d are disposed at the same opening pitch from the lower portion to the upper portion of the reaction tube 203 and have the same opening area.

The nozzle 233c is installed along the inner wall of the reaction tube 203 to rise upward in the stacking direction of the wafers 200 in an end of the buffer chamber 237 opposite to the end thereof in which the gas supply holes 248d is formed. That is, the nozzle 233c is installed at the side of the wafer arrangement region. The nozzle 233c is configured as an L-shaped long nozzle and has its horizontal portion installed to penetrate through the lower sidewall of the manifold 209 and its vertical portion installed to rise from one end of the wafer arrangement region toward the other end thereof. A plurality of gas supply holes 248c through which gas is supplied is formed in a side surface of the nozzle 233c. The gas supply holes 248c are opened toward the center of the buffer chamber 237. The gas supply holes 248c are disposed at the same opening pitch from the lower portion to the upper portion of the reaction tube 203 in the same way as the gas supply holes 248d of the buffer chamber 237. The plurality of gas supply holes 248c may have the same opening area and the same opening pitch from an upstream side (lower portion) to an downstream side (upper portion) when a pressure difference between the inside of the buffer chamber 237 and the inside of the process chamber 201 is small. However, when the pressure difference is large, the opening area of each gas supply hole 248c may be set larger and the opening pitch of each gas supply hole 248c may be set smaller at the downstream side than the upstream side.

In the embodiment, by adjusting the opening area or opening pitch of each gas supply hole 248c of the nozzle 233c from the upstream side to the downstream side as described above, gases may be ejected at an almost same flow rate from the respective gas supply holes 248c despite a flow velocity difference. In addition, the gases ejected from the respective gas supply holes 248c are first introduced into the buffer chamber 237, and a flow velocity difference of the gases is uniformized in the buffer chamber 237. That is, the gases ejected from the respective gas supply holes 248c of the nozzle 233c into the buffer chamber 237 are mitigated in particle velocity of the respective gases in the buffer chamber 237, and then are ejected from the respective gas supply holes 248d of the buffer chamber 237 into the process chamber 201. Therefore, the gases ejected from the respective gas supply holes 248c of the nozzle 233c into the buffer chamber 237 have a uniform flow rate and flow velocity when the gases are ejected from the respective gas supply holes 248d of the buffer chamber 237 into the process chamber 201.

An MFC 241k and a valve 243k are installed in the gas supply pipe 232k in this order from an upstream direction. In addition, one leading end of the gas supply pipe 232k is connected to the gas supply pipe 232a, thereby being connected to the nozzle 233a via the gas supply pipe 232a. Further, the other leading end of the gas supply pipe 232k is connected to the gas supply pipe 232b, thereby being connected to the nozzle 233b via the gas supply pipe 232b.

An MFC 241l and a valve 243l are installed in the gas supply pipe 232l in this order from an upstream direction. In addition, an inert gas supply pipe 232m is connected to the gas supply pipe 232l at a downstream side of the valve 243l. An MFC 241m and a valve 243m are installed in the inert gas supply pipe 232m in this order from an upstream direction. In addition, the above-described nozzle 233d is connected to a leading end of the gas supply pipe 232l.

The nozzle 233d is installed in an annular space between the inner wall of the manifold 209 and a side surface of a heat insulating member 218 described later so as to rise along the inner wall of the manifold 209) toward an upper portion of the heat insulating member 218. That is, the nozzle 233d is installed along the heat insulating member 218 in a region horizontally surrounding the heat insulating member 218 under the wafer arrangement region. The nozzle 233d is configured as an L-shaped short nozzle and has its horizontal portion installed to penetrate through the sidewall of the manifold 209 and its vertical portion installed to rise at least from a lower portion of the heat insulating member 218 toward an upper portion thereof. In addition, gas supply holes 248e through which gas is supplied are formed in a leading end of the nozzle 233d. The gas supply holes 248e are opened toward the upper portion of the reaction tube 203. Thus, the gas supply holes 248e can supply gas toward the inner wall surface of the manifold 209 at a lower position than the positions at which the nozzle 233a and the nozzle 233b supply gases.

In the method of supplying gas according to the embodiment, the gas may be transferred through the nozzles 233a, 233b and 233c and the buffer chamber 237 disposed in an annular longitudinal space, i.e., a cylindrical space, defined by the inner wall of the reaction tube 203 and ends of the stacked wafers 200. The gas is first ejected into the reaction tube 203 near the wafers 200 through the gas supply holes 248a, 248b, 248c and 248d opened in the nozzles 233a, 233b, and 233c and the buffer chamber 237, respectively. Thus, a main flow of the gas in the reaction tube 203 follows a direction parallel to surfaces of the wafers 200, i.e., the horizontal direction. With this configuration, the gas can be uniformly supplied to the respective wafers 200, and thus, a film thickness of a thin film formed on each of the wafers 200 can be uniformized. In addition, a residual gas after the reaction flows toward an exhaust port, i.e., an exhaust pipe 231 described later, but a flow direction of the residual gas is not limited to the vertical direction but may be appropriately adjusted by a position of the exhaust port.

As a first precursor gas containing a predetermined element, i.e. a first precursor gas containing silicon (Si) as the predetermined element (first silicon-containing gas), a hexachlorodisilane (Si₂Cl₆, abbreviation: HCDS) gas, for example, is supplied from the gas supply pipe 232a into the process chamber 201 through the MFC 241a, the valve 243a, and the nozzle 233a. When a liquid precursor in a liquid state under normal temperature and pressure, such as HCDS, is used, the liquid precursor is vaporized by a vaporization system, such as a vaporizer or a bubbler, and supplied as the first precursor gas.

As a second precursor gas containing a predetermined element, i.e., a second precursor gas containing silicon (Si) as the predetermined element (second silicon-containing gas), a dichlorosilane (SiH₂Cl₂, abbreviation: DCS) gas, for example, is supplied from the gas supply pipe 232b into the process chamber 201 through the MFC 241b, the valve 243b, and the nozzle 233b. When a liquid precursor in a liquid state under normal temperature and pressure, such as DCS, is used, the liquid precursor is vaporized by a vaporization system, such as a vaporizer or a bubbler, and supplied as the second precursor gas.

As a gas containing nitrogen (nitrogen-containing gas), i.e., a nitriding gas, an ammonia (NH₃) gas, for example, is supplied from the gas supply pipe 232c into the process chamber 201 through the MFC 241c, the valve 243c, the nozzle 233c, and the buffer chamber 237.

As a gas containing oxygen (oxygen-containing gas), i.e., an oxidizing gas, an oxygen (O₂) gas, for example, is supplied from the gas supply pipe 232d into the process chamber 201 through the MFC 241d, the valve 243d, the gas supply pipe 232c, the nozzle 233c, and the buffer chamber 237.

As a gas containing hydrogen (hydrogen-containing gas), i.e., a reducing gas, a hydrogen (H₂) gas, for example, is supplied from the gas supply pipe 232e into the process chamber 201 through the MFC 241e, the valve 243e, the gas supply pipe 232c, the nozzle 233c, and the buffer chamber 237.

As the hydrogen-free fluorine-based gas, a chlorine trifluoride (ClF₃) gas, for example, is supplied from the gas supply pipe 232k into the process chamber 201 through the MFC 241k, the valve 243k, the gas supply pipe 232a, and the nozzle 233a and is also supplied into the process chamber 201 through the MFC 241k, the valve 243k, the gas supply pipe 232b, and the nozzle 233b.

The hydrogen fluoride (HF) gas is supplied from the gas supply pipe 232l into the process chamber 201 through the MFC 241l, the valve 243l, and the nozzle 233d.

As an inert gas, a nitrogen (N₂) gas, for example, is supplied from the gas supply pipes 232f to 232j and 232m into the process chamber 201 through the MFCs 241f to 241j and 241m, the valves 243f to 243j and 243m, the gas supply pipes 232a to 232e and 232l, the nozzles 233a to 233d, and the buffer chamber 237, respectively.

When the above-described gases are respectively flowed from the gas supply pipes, a first precursor gas supply system configured to supply the first precursor gas containing the predetermined element, i.e., a first silicon-containing gas supply system, is mainly configured by the gas supply pipe 232a, the MFC 241a, and the valve 243a. The nozzle 233a may also be included in the first precursor gas supply system. The first precursor gas supply system may be referred to as a first precursor supply system.

In addition, a second precursor gas supply system configured to supply the second precursor gas containing the predetermined element, i.e., a second silicon-containing gas supply system, is mainly configured by the gas supply pipe 232b, the MFC 241b, and the valve 243b. The nozzle 233b may also be included in the second precursor gas supply system. The second precursor gas supply system may be referred to as a second precursor supply system.

A nitrogen-containing gas (nitriding gas) supply system is mainly configured by the gas supply pipe 232c, the MFC 241c, and the valve 243c. The nozzle 233c and the buffer chamber 237 may also be included in the nitrogen-containing gas supply system.

Further, an oxygen-containing gas (oxidizing gas) supply system is mainly configured by the gas supply pipe 232d, the MFC 241d, and the valve 243d. The nozzle 233c and the buffer chamber 237 may also be included in the oxygen-containing gas supply system.

Furthermore, a hydrogen-containing gas (reducing gas) supply system is mainly configured by the gas supply pipe 232e, the MFC 241e, and the valve 243e. The nozzle 233c and the buffer chamber 237 may also be included in the hydrogen-containing gas supply system.

A fluorine-based gas supply system configured to supply the hydrogen-free fluorine-based gas is mainly configured by the gas supply pipe 232k, the MFC 241k, and the valve 243k. Portions of the gas supply pipes 232a and 232b in downstream sides of junctions with the gas supply pipe 232k, and the nozzles 233a and 233b may also be included in the fluorine-based gas supply system.

In addition, a hydrogen fluoride gas supply system configured to supply a hydrogen fluoride gas is mainly configured by the gas supply pipe 232l, the MFC 241l, and the valve 243l. The nozzle 233d may also be included in the hydrogen fluoride gas supply system.

Further, an inert gas supply system is mainly configured by the inert gas supply pipes 232f to 232j and 232m, the MFCs 241f to 241j and 241m, and the valves 243f to 243j and 243m. Portions of the gas supply pipes 232a to 232e and 232l in downstream sides of junctions with the inert gas supply pipes 232f to 232j and 232m, the nozzles 233a to 233d, and the buffer chamber 237 may also be included in the inert gas supply system. The inert gas supply system also acts as a purge gas supply system.

Although in the embodiment, the HCDS gas and the DCS gas are respectively supplied from the separate nozzles into the process chamber 201, they may be supplied from the same nozzle. Also, although in the embodiment, the NH₃ gas, the 0, gas and the 12 gas are supplied from the same nozzle into the process chamber 201 (into the buffer chamber 237), they may be respectively supplied into the process chamber 201 from separate nozzles, or only the H₂ gas may be supplied from another nozzle into the process chamber 201. However, since the number of nozzles can be reduced if plural kinds of gases share a nozzle, there are advantages in that the apparatus cost can be reduced and the maintenance is also easily performed. In addition, the nozzle configured to supply the HCDS gas or the DCS gas may be commonly used as the nozzle configured to supply the H₂ gas. That is, the HCDS gas and the H₂ gas may be supplied from the same nozzle, the DCS gas and the H₂ gas may be supplied from the same nozzle, or the HCDS gas, the DCS gas and the H₂ gas may be supplied from the same nozzle. Also, since it is thought that in a film forming temperature range described later, the HCDS gas or the DCS gas does not react with the H₂ gas but respectively reacts with the NH₃ gas or the O₂ gas, the nozzle configured to supply the HCDS gas or the DCS gas is preferably separate from the nozzle configured to supply the NH₃ gas or the O₂ gas.

While in the embodiment, the HCDS gas and the ClF₃ gas are supplied from the same nozzle into the process chamber 201, they may be respectively supplied from separate nozzles. However, since the number of nozzles can be reduced if the HCDS gas and the ClF₃ gas are supplied from the same nozzle, there are advantages in that the apparatus cost can be reduced and the maintenance is also easily performed. Further, if the HCDS gas and the ClF₃ gas are supplied from the same nozzle, since the inside of the nozzle can be cleaned with the ClF₃ gas, a substance including HCDS or silicon (Si) decomposed from HCDS, which adheres to or is deposited on the inside of the nozzle, can be removed. Accordingly, it is more preferred that the nozzle configured to supply the HCDS gas and the nozzle configured to supply the ClF₃ gas be the same.

Also, while in the embodiment, the DCS gas and the ClF₃ gas are supplied from the same nozzle into the process chamber 201, they may be respectively supplied from separate nozzles. However, since the number of nozzles can be reduced if the DCS gas and the ClF₃ gas are supplied from the same nozzle, there are advantages in that the apparatus cost can be reduced and the maintenance is also easily performed. Further, if the DCS gas and the ClF₃ gas are supplied from the same nozzle, since the inside of the nozzle can be cleaned with the ClF₃ gas, a substance including DCS or silicon decomposed from DCS, which adheres to or is deposited on the inside of the nozzle, can be removed. Accordingly, it is more preferred that the nozzle configured to supply the DCS gas and the nozzle configured to supply the ClF₃ gas be the same.

In the buffer chamber 237, as illustrated in FIG. 2, a first rod-shaped electrode 269 that is a first electrode having an elongated structure and a second rod-shaped electrode 270 that is a second electrode having an elongated structure are disposed to span from the lower portion to the upper portion of the reaction tube 203 in the stacking direction of the wafers 200. Each of the first rod-shaped electrode 269 and the second rod-shaped electrode 270 is disposed in parallel to the nozzle 233c. Each of the first rod-shaped electrode 269 and the second rod-shaped electrode 270 is covered with and protected by an electrode protection tube 275, which is a protection tube for protecting each electrode from an upper portion to a lower portion thereof. Any one of the first rod-shaped electrode 269 and the second rod-shaped electrode 270 is connected to a high-frequency power source 273 through a matcher 272, and the other one is connected to a ground corresponding to a reference electric potential. By applying high-frequency power from the high-frequency power source 273 between the first rod-shaped electrode 269 and the second rod-shaped electrode 270 through the matcher 272, plasma is generated in a plasma generation region 224 between the first rod-shaped electrode 269 and the second rod-shaped electrode 270. A plasma source serving as a plasma generator (plasma generating part) is mainly configured by the first rod-shaped electrode 269, the second rod-shaped electrode 270, and the electrode protection tubes 275. The matcher 272 and the high-frequency power source 273 may also be included in the plasma source. Also, as described later, the plasma source functions as an activating mechanism that activates gas into plasma.

The electrode protection tube 275 has a structure in which each of the first rod-shaped electrode 269 and the second rod-shaped electrode 270 can be inserted into the buffer chamber 237 in a state where each of the first rod-shaped electrode 269 and the second rod-shaped electrode 270 is isolated from an internal atmosphere of the buffer chamber 237. Here, when an internal oxygen concentration of the electrode protection tube 275 is equal to an oxygen concentration in an ambient air (atmosphere), each of the first rod-shaped electrode 269 and the second rod-shaped electrode 270 inserted into the electrode protection tubes 275 is oxidized by the heat generated by the heater 207. Therefore, by charging the inside of the electrode protection tube 275 with an inert gas such as nitrogen gas, or by purging the inside of the electrode protection tube 275 with an inert gas such as nitrogen gas using an inert gas purging mechanism, the internal oxygen concentration of the electrode protection tube 275 decreases, thereby preventing oxidation of the first rod-shaped electrode 269 or the second rod-shaped electrode 270.

The exhaust pipe 231 for exhausting an internal atmosphere of the process chamber 201 is installed at the reaction tube 203. A vacuum exhaust device, for example, a vacuum pump 246, is connected to the exhaust pipe 231 through a pressure sensor 245, which is a pressure detector (pressure detecting part) for detecting an internal pressure of the process chamber 201, and an auto pressure controller (APC) valve 244, which is a pressure adjuster (pressure adjusting part). The APC valve 244 is configured to perform/stop vacuum exhaust in the process chamber 201 by opening/closing the valve with the actuated vacuum pump 246, and further to adjust the internal pressure of the process chamber 201 by adjusting a degree of the valve opening with the actuated vacuum pump 246. An exhaust system is mainly configured by the exhaust pipe 231, the APC valve 244, and the pressure sensor 245. Also, the vacuum pump 246 may be included in the exhaust system. The exhaust system is configured to adjust the degree of the valve opening of the APC valve 244 based on pressure information detected by the pressure sensor 245 while operating the vacuum pump 246 such that the internal pressure of the process chamber 201 is vacuum exhausted to a predetermined pressure (a vacuum level). In addition, the exhaust pipe 231 may be installed at the manifold 209 instead of the reaction tube 203.

A seal cap 219, which functions as a furnace port cover configured to hermetically seal a lower end opening of the manifold 209, is installed under the manifold 209. The seal cap 219 is configured to contact the lower end of the manifold 209 from the below in the vertical direction. The seal cap 219, for example, may be formed of metal such as stainless and have a disc shape. An O-ring 220, which is a seal member in contact with the lower end of the manifold 209, is installed at an upper surface of the seal cap 219. A rotary mechanism 267 configured to rotate the boat 217, which is a substrate holder to be described later, is installed below the seal cap 219. A rotary shaft 255 of the rotary mechanism 267 passes through the seal cap 219 to be connected to the boat 217. The rotary mechanism 267 is configured to rotate the wafers 200 by rotating the boat 217. The seal cap 219 is configured to be vertically elevated or lowered by a boat elevator 115, which is an elevation mechanism vertically disposed at the outside of the reaction tube 203. The boat elevator 115 is configured to enable the boat 217 to be loaded into or unloaded from the process chamber 201 by elevating or lowering the seal cap 219. That is, the boat elevator 115 is configured as a transfer device (transfer mechanism) that transfers the boat 217, i.e., the wafers 200, into and out of the process chamber 201.

The boat 217, which is used as a substrate support, is made of a heat resistant material such as quartz or silicon carbide and is configured to support a plurality of the wafers 200 horizontally stacked in multiple stages with the centers of the wafers 200 concentrically aligned. A heat insulating member 218 formed of a heat resistant material such as quartz or silicon carbide is installed at a lower portion of the boat 217 and configured such that the heat from the heater 207 cannot be transferred to the seal cap 219. In addition, the heat insulating member 218 may be configured by a plurality of heat insulating plates formed of a heat resistant material such as quartz or silicon carbide, and a heat insulating plate holder configured to support the heat insulating plates in a horizontal posture in a multi-stage manner.

A temperature sensor 263, which is a temperature detector, is installed in the reaction tube 203. Based on temperature information detected by the temperature sensor 263, an electric conduction state to the heater 207 is adjusted such that the inside of the process chamber 201 has a desired temperature distribution. The temperature sensor 263 is configured in an L-shape similar to the nozzles 233a to 233c and installed along the inner wall of the reaction tube 203.

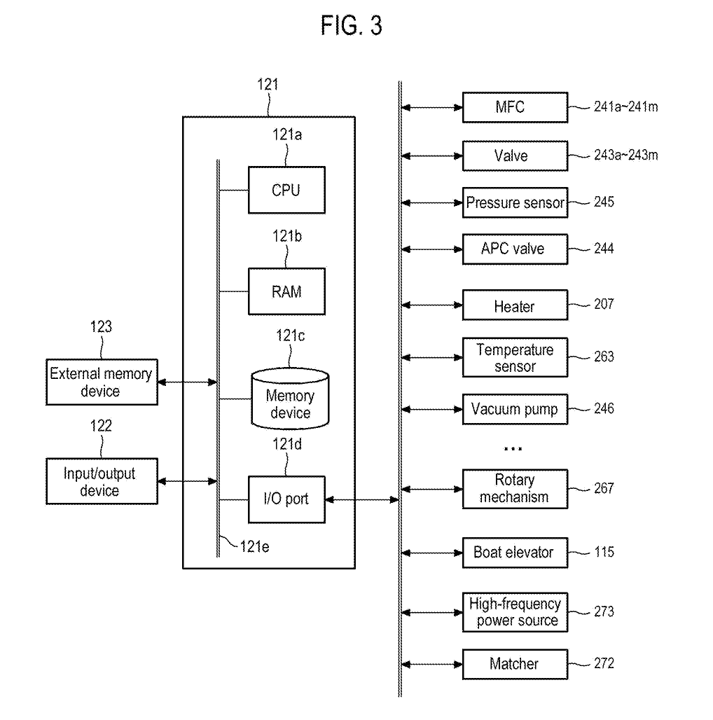

As illustrated in FIG. 3, a controller 121, which is a control unit (control part), is configured as a computer including a central processing unit (CPU) 121a, a random access memory (RAM) 121b, a memory device 121c, and an I/O port 121d. The RAM 121b, the memory device 121c and the I/O port 121d are configured to exchange data with the CPU 121a via an internal bus 121e. An input/output device 122, for example, including a touch panel or the like, is connected to the controller 121.

The memory device 121c is configured by, for example, a flash memory, a hard disc drive (HDD), or the like. A control program for controlling operations of the substrate processing apparatus, a process recipe, in which a sequence or condition for processing a substrate described later is written, a cleaning recipe, in which a sequence or condition for cleaning processing described later is written, or the like is readably stored in the memory device 121c. The process recipe functions as a program for the controller 121 to execute each sequence in the substrate processing process, which will be described later, to obtain a predetermined result. The cleaning recipe functions as a program for the controller 121 to execute each sequence in the cleaning process, which will be described later, to obtain a predetermined result. Hereinafter, the process recipe, cleaning recipe or control program may be generally referred to as a program. Also, when the term “program” is used herein, it may include the case in which only any one of the process recipe, the cleaning recipe, and the control program is included, or the case in which any combination of the process recipe, the cleaning recipe, and the control program is included. In addition, the RAM 121b is configured as a memory area (work area) in which a program or data read by the CPU 121a is temporarily stored.

The I/O port 121d is connected to the MFCs 241a to 241m, the valves 243a to 243m, the pressure sensor 245, the APC valve 244, the vacuum pump 246, the heater 207, the temperature sensor 263, the rotary mechanism 267, the boat elevator 115, the high-frequency power source 273, the matcher 272 and the like.

The CPU 121a is configured to read and execute the control program from the memory device 121c. According to an input of an operation command from the input/output device 122, the CPU 121a reads the process or cleaning recipe from the memory device 121c. In addition, the CPU 121a is configured to control the flow rate controlling operation of various types of gases by the MFCs 241a to 241m, the opening/closing operation of the valves 243a to 243m, the opening/closing operation of the APC valve 244 and the pressure adjusting operation by the APC valve 244 based on the pressure sensor 245, the temperature adjusting operation of the heater 207 based on the temperature sensor 263, the operation of starting and stopping the vacuum pump 246, the rotation and rotation speed adjusting operation of the boat 217 by the rotary mechanism 267, the elevation operation of the boat 217 by the boat elevator 115, the operation of supplying power by the high-frequency power source 273, the impedance adjusting operation of the matcher 272, and the like according to contents of the read process or cleaning recipe.

Moreover, the controller 121 is not limited to being configured as a dedicated computer but may be configured as a general-purpose computer. For example, the controller 121 according to the embodiment may be configured by preparing an external memory device 123 (for example, a magnetic tape, a magnetic disc such as a flexible disc or a hard disc, an optical disc such as a CD or DVD, a magneto-optical disc such as an MO, a semiconductor memory such as a USB memory or a memory card), in which the program is stored, and installing the program on the general-purpose computer using the external memory device 123. Also, a means for supplying a program to a computer is not limited to the case in which the program is supplied through the external memory device 123. For example, the program may be supplied using a communication means such as the Internet or a dedicated line, rather than through the external memory device 123. Also, the memory device 121c or the external memory device 123 is configured as a non-transitory computer-readable recording medium. Hereinafter, these means for supplying the program will be simply referred to as a recording medium. In addition, when the term “recording medium” is used herein, it may include a case in which only the memory device 121c is included, a case in which only the external memory device 123 is included, or a case in which both the memory device 121c and the external memory device 123 are included.

### (2) Substrate Processing Process

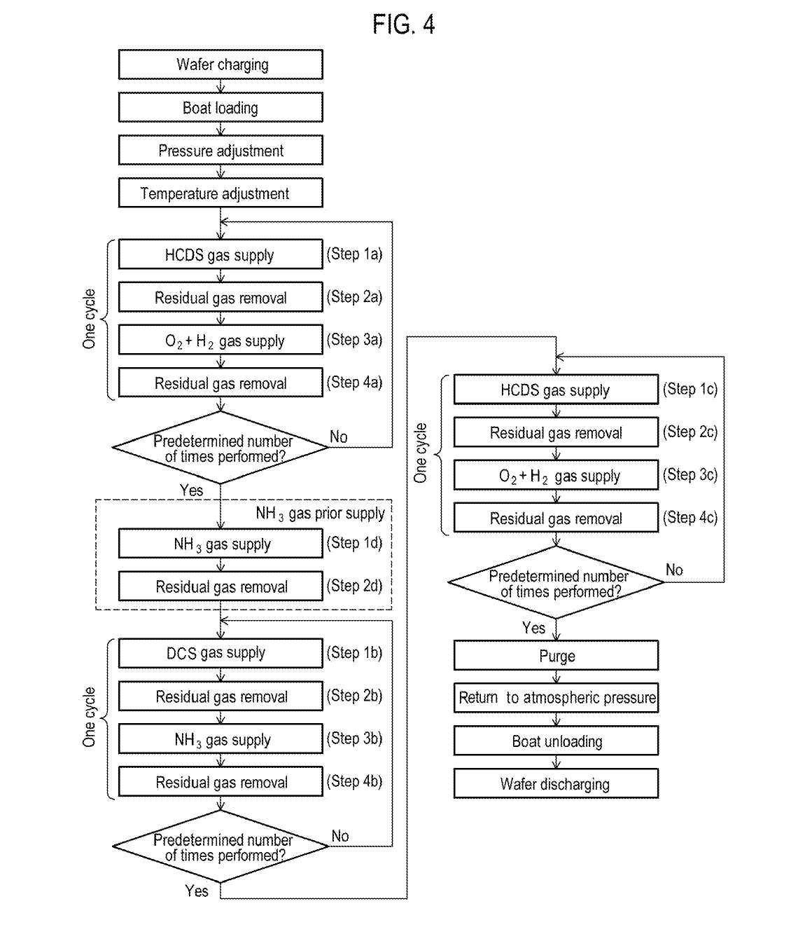

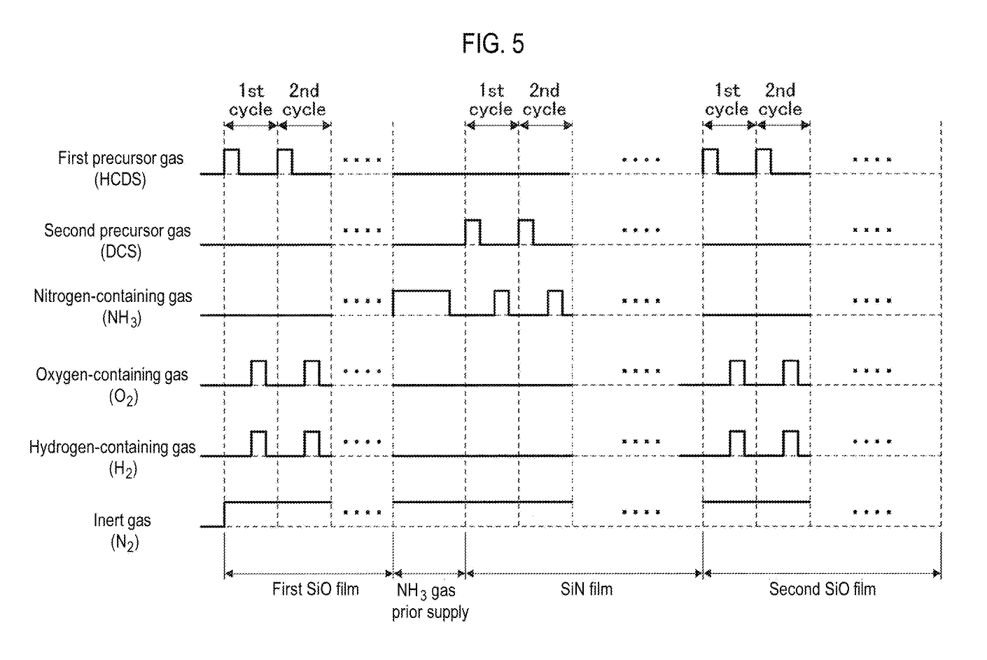

Next, an example of forming an insulating film having an ONO stack structure made up by stacking a first oxide film, a nitride film, and a second oxide film on a substrate in this order using the processing furnace 202 of the above-described substrate processing apparatus, which is one of the processes of manufacturing a semiconductor device, will be described with reference to FIGS. 4 and 5. Further, in the following description, operations of the respective parts constituting the substrate processing apparatus are controlled by the controller 121.

In the embodiment, a stacked film of oxide and nitride films is formed on a wafer 200 in the process chamber 201, which includes the reaction tube 203 installed inside the heater 207 and the manifold 209 configured to support the reaction tube 203 and installed under the heater 207, by alternately performing a process of forming the oxide film and a process of forming the nitride film, wherein the process of forming the oxide film is performed by alternately supplying the first precursor gas to the wafer 200 in the process chamber 201 and supplying the oxygen-containing gas and the hydrogen-containing gas to the wafer 200 in the process chamber 201 under a pressure less than atmospheric pressure once or more, and the process of forming the nitride film is performed by alternately supplying the second precursor gas to the wafer 200 in the process chamber 201 and supplying the nitrogen-containing gas to the wafer 200 in the process chamber 201 once or more.

Further, in the embodiment, after the above-described processes are performed, the inside of the process chamber 201 is cleaned. The cleaning of the inside of the process chamber 201 will be described in detail later.

Here, the process of forming the oxide film and the process of forming the nitride film are continuously performed in-situ in the process chamber 201. Further, in the embodiment, the first precursor gas, the oxygen-containing gas, the hydrogen-containing gas, the second precursor gas, and the nitrogen-containing gas are thermally activated or plasma-activated.

Hereinafter, a film forming sequence of the embodiment will be described in detail. Here, using the HCDS gas as the first precursor gas, the O₂ gas as the oxygen-containing gas, the H₂ gas as the hydrogen-containing gas, and the N₂ gas as the diluent gas or purge gas, a silicon oxide film (SiO₂ film, hereinafter, also referred to as a first silicon oxide film or a first SiO film) as the oxide film is formed on the wafer 200 as a substrate. Thereafter, using the DCS gas as the second precursor gas, the NH₃ gas as the nitrogen-containing gas, and the N₂ gas as the diluent gas or purge gas, a silicon nitride film (Si₃N₄ film, hereinafter, also referred to as a SiN film) as the nitride film is formed on the silicon oxide film. Thereafter, using the HCDS gas as the first precursor gas, the O₂ gas as the oxygen-containing gas, the H₂ gas as the hydrogen-containing gas, and the N₂ gas as the diluent gas or purge gas, a silicon oxide film (SiO₂ film, hereinafter, also referred to as a second silicon oxide film or a second SiO film) is formed on the silicon nitride film. Accordingly, the insulating film having the ONO stack structure is made up by stacking the first silicon oxide film, the silicon nitride film, and the second silicon oxide film in this order on the wafer 200. In addition, as described later, the process of forming the first silicon oxide film, the process of forming the silicon nitride film, and the process of forming the second silicon oxide film are continuously performed (in-situ) in the same process vessel.

Moreover, when the term “wafer” is used herein, it may refer to “the wafer itself” or “a stacked body (a collected body) of the wafer and predetermined layers or films formed on the surface of the wafer,” i.e., the wafer including the predetermined layers or films formed on the surface may be referred to as a wafer. In addition, the phrase “a surface of a wafer” as used herein may refer to “a surface (an exposed surface) of a wafer itself” or “a surface of a predetermined layer or film formed on the wafer, i.e., the uppermost surface of the wafer, which is a stacked body.”

Accordingly, “a predetermined gas is supplied to a wafer” may mean that “a predetermined gas is directly supplied to a surface (an exposed surface) of a wafer itself” or that “a predetermined gas is supplied to a layer or a film formed on a wafer, i.e., on the uppermost surface of a wafer as a stacked body.” Also, “a predetermined layer (or film) is formed on a wafer” may mean that “a predetermined layer (or film) is directly formed on a surface (an exposed surface) of a wafer itself” or that “a predetermined layer (or film) is formed on a layer or a film formed on a wafer, i.e., on the uppermost surface of a wafer as a stacked body.”

Moreover, the term “substrate” as used herein may be synonymous with the term “wafer.” and in this case, the terms “wafer” and “substrate” may be used interchangeably in the above description.

### (Wafer Charging and Boat Loading)

When the plurality of wafers 200 are charged on the boat 217 (wafer charging), as illustrated in FIG. 1, the boat 217 supporting the plurality of wafers 200 is raised by the boat elevator 115 to be loaded into the process chamber 201 (boat loading). In this state, the seal cap 219 seals the lower end of the manifold 209 via the O-ring 220.

### (Pressure Adjustment and Temperature Adjustment)

The inside of the process chamber 201 is vacuum exhausted by the vacuum pump 246 to a desired pressure (vacuum level). Here, the internal pressure of the process chamber 201 is measured by the pressure sensor 245, and the APC valve 244 is feedback-controlled based on the measured pressure information (pressure adjustment). Also, the vacuum pump 246 maintains a regular operation state at least until processing of the wafers 200 is terminated. Further, the process chamber 201 is heated by the heater 207 to a desired temperature. Here, an electrical conduction state to the heater 207 is feedback-controlled based on the temperature information detected by the temperature sensor 263 until the inside of the process chamber 201 reaches a desired temperature distribution (temperature adjustment). In addition, the heating of the inside of the process chamber 201 by the heater 207 is continuously performed at least until processing of the wafers 200 is terminated. Next, the boat 217 and wafers 200 begin to be rotated by the rotary mechanism 267. Furthermore, the rotation of the boat 217 and wafers 200 by the rotary mechanism 267 is continuously performed at least until processing of the wafers 200 is terminated.

### (Process of Forming First Silicon Oxide Film)

Thereafter, the first silicon oxide film having a predetermined film thickness is formed on the wafer 200 by setting the following Steps 1a to 4a as one cycle and performing the cycle once or more.

### [Step 1a]

The valve 243a is opened to flow the HCDS gas into the first gas supply pipe 232a. A flow rate of the HCDS gas flowing into the first gas supply pipe 232a is adjusted by the MFC 241a. The flow rate-adjusted HCDS gas is supplied into the process chamber 201, which is kept in a heated and depressurized state, through the gas supply holes 248a of the nozzle 233a and exhausted through the exhaust pipe 231 (HCDS gas supply).

At the same time, the N₂ gas may be supplied from the inert gas supply pipe 232f by opening the valve 243f. A flow rate of the N₂ gas is adjusted by the MFC 241f, and the N, gas is supplied into the gas supply pipe 232a. The flow rate-adjusted N₂ gas is mixed with the flow rate-adjusted HCDS gas in the gas supply pipe 232a, and the mixed gas is supplied into the process chamber 201, which is kept in the heated and depressurized state, through the gas supply holes 248a of the nozzle 233a and exhausted through the exhaust pipe 231. Here, in order to prevent infiltration of the HCDS gas into the buffer chamber 237 or the nozzles 233b to 233d, the valves 243g to 243j and 243m are opened to flow the N₂ gas into the inert gas supply pipes 232g to 232j and 232m. The N₂ gas is supplied into the process chamber 201 through the gas supply pipes 232b to 232e and 232l, the nozzles 233b to 233d, and the buffer chamber 237 and exhausted through the exhaust pipe 231.

At this time, the APC valve 244 is appropriately adjusted so that the internal pressure of the process chamber 201 is maintained at a pressure less than atmospheric pressure, for example, within a range of 10 to 1,000 Pa. A supply flow rate of the HCDS gas controlled by the MFC 241a is set to fall within a range of, for example, 10 to 1,000 sccm (0.01 to 1 slm). A supply flow rate of the N₂ gas controlled by each of the MFCs 241f to 241j and 241m is set to fall within a range of, for example, 100 to 2,000 seem (0.1 to 2 slm). A time of supplying the HCDS gas to the wafer 200, i.e., a gas supply time (irradiation time), is set to fall within a range of, for example, 1 to 120 seconds. A temperature of the heater 207 is set such that a CVD reaction occurs within the process chamber 201 in the above-described pressure range. That is, the temperature of the heater 207 is set such that a temperature of the wafer 200 falls within a range of, for example, 350 to 800 degrees C., more specifically, 450 to 800 degrees C., or further more specifically, 550 to 750 degrees C. In addition, when the temperature of the wafer 200 is less than 350 degrees C., it becomes difficult for the HCDS gas to be decomposed and adsorbed onto the wafer 200. Further, a remarkably improved oxidizing power effect is obtained in Step 3a described later by increasing the temperature of the wafer 200 to 450 degrees C. or more. Also, it is possible to sufficiently decompose the HCDS gas by increasing the temperature of the wafer 200 to 550 degrees C. or more. Further, when the temperature of the wafer 200 exceeds 750 degrees C., specifically, 800 degrees C., the film thickness uniformity is remarkably deteriorated as a CVD reaction is strengthened. Accordingly, the temperature of the wafer 200 may be set to fall within a range of 350 to 800 degrees C., more specifically, 450 to 800 degrees C., or further more specifically, 550 to 750 degrees C.

As the HCDS gas is supplied into the process chamber 201 under the above-described conditions, i.e., the condition where a CVD reaction occurs, a silicon-containing layer having a thickness of, for example, less than one atomic layer to several atomic layers is formed on the wafer 200 (an underlayer film on the surface thereof). The silicon-containing layer may be an adsorption layer of the HCDS gas, a silicon layer (Si layer), or both of these. However, it is preferred that the silicon-containing layer be a Si and Cl-containing layer.

Here, the silicon layer is a generic name including a discontinuous layer in addition to a continuous layer formed of Si, or a silicon thin film formed by laminating them. Also, a continuous layer formed of Si may be referred to as the silicon thin film. In addition, Si constituting the silicon layer includes Si, in which bonding to Cl is not completely broken.

Moreover, the adsorption layer of the HCDS gas may include a chemisorption layer in which gas molecules of the HCDS gas are discontinuous, in addition to a chemisorption layer in which the gas molecules of the HCDS gas are continuous. That is, the adsorption layer of the HCDS gas may include a chemisorption layer that contains HCDS molecules having a thickness of one molecular layer or less. Further, HCDS (Si₂Cl₆) molecules constituting the adsorption layer of the HCDS gas also contains molecules in which bonding of Si and Cl is partially broken (Si, Cl_{y} molecules). That is, the adsorption layer of the HCDS gas includes a chemisorption layer in which Si₂Cl₆ molecules and/or SiₓCl_{y} molecules are continuous or a chemisorption layer in which Si₂Cl₆ molecules and/or SiₓCl_{y} molecules are discontinuous. Also, a layer having a thickness of less than one atomic layer refers to a discontinuously formed atomic layer, and a layer having a thickness of one atomic layer refers to a continuously formed atomic layer. In addition, a layer having a thickness of less than one molecular layer refers to a discontinuously formed molecular layer, and a layer having a thickness of one molecular layer refers to a continuously formed molecular layer.

Under a condition in which the HCDS gas is autolyzed (pyrolyzed), i.e., under a condition in which a pyrolysis reaction of the HCDS gas occurs, the silicon layer is formed by depositing Si on the wafer 200. Under a condition in which the HCDS gas is not autolyzed (pyrolyzed), i.e., under a condition in which a pyrolysis reaction of the HCDS gas does not occur, the adsorption layer of the HCDS gas is formed by adsorbing the HCDS gas onto the wafer 200. The formation of the silicon layer on the wafer 200 results in a higher film forming rate than the formation of the adsorption layer of the HCDS gas on the wafer 200. For example, as the silicon layer having a thickness of several atomic layers is formed on the wafer 200 and oxidizing power is increased in Step 3a described later, a cycle rate can be increased to be capable of resulting in a higher film forming rate.

When the thickness of the silicon-containing layer formed on the wafer 200 exceeds several atomic layers, an effect of the oxidation (modification) reaction in Steps 3a described later does not reach the entire silicon-containing layer. In addition, a minimum value of the thickness of the silicon-containing layer that can be formed on the wafer 200 is less than one atomic layer. Accordingly, the thickness of the silicon-containing layer may range from less than one atomic layer to several atomic layers. When the thickness of the silicon-containing layer is one atomic layer or less (i.e., one atomic layer or less than one atomic layer), an effect of the oxidation (modification) reaction in Step 3a described later can be relatively increased, and thus a time required for the oxidation (modification) reaction in Step 3a can be reduced. A time required for forming the silicon-containing layer in Step 1a can also be reduced. As a result, a processing time per one cycle can be reduced, and a total processing time can also be reduced. That is, the film forming rate can be increased. In addition, as the thickness of the silicon-containing layer is one atomic layer or less, it may become easier to maintain and control the film thickness uniformity.

The first precursor gas (first silicon-containing gas) may include not only an inorganic precursor such as a tetrachlorosilane, i.e., silicon tetrachloride (SiCl₄, abbreviation: STC) gas, trichlorosilane (SiHCl₃, abbreviation: TCS) gas, dichlorosilane (SiH₂Cl₂, abbreviation: DCS) gas, monochlorosilane (SiH₃Cl, abbreviation: MCS) gas, monosilane(SiH₄) gas, or the like, in addition to the hexachlorodisilane (Si₂Cl₆, abbreviation: HCDS) gas, but also an organic precursor such as tetrakis(dimethylamino)silane (Si[N(CH₃)₂]₄, abbreviation: 4DMAS) gas, tris(dimethylamino)silane (Si[N(CH₃)₂]₃H, abbreviation: 3DMAS) gas, bis(diethylamino)silane (Si[N(C₂H₅)₂]H₂H₂, abbreviation: 2DEAS) gas, or bis(tert-butylamino)silane (SiH₂[NH(C₄H₉)]₂, abbreviation: BTBAS) gas. The inert gas may include a rare gas such as Ar gas, He gas, Ne gas, Xe gas, and the like, in addition to the N₂ gas.

### [Step 2a]

After the silicon-containing layer is formed on the wafer 200, the valve 243a is closed to stop the supply of the HCDS gas. At this time, while the APC valve 244 of the exhaust pipe 231 is in an open state, the inside of the process chamber 201 is vacuum exhausted by the vacuum pump 246, and the HCDS gas remaining in the process chamber 201 which does not react or remains after contributing to the formation of the silicon-containing layer is removed from the process chamber 201. In addition, the valves 243f to 243j and 243m are in an open state, and the supply of the N₂ gas into the process chamber 201 is maintained. The N₂ gas acts as a purge gas, and thus, the HCDS gas remaining in the process chamber 201 which does not react or remains after contributing to the formation of the silicon-containing layer can be more effectively removed from the process chamber 201 (residual gas removal).

Moreover, in this case, the gas remaining in the process chamber 201 may not be completely removed, and the inside of the process chamber 201 may not be completely purged. When the gas remaining in the process chamber 201 is very small in amount, there is no adverse effect generated in Step 3a performed thereafter. Here, the amount of the N₂ gas supplied into the process chamber 201 need not be large, and for example, approximately the same amount of the N₂ gas corresponding to the volume of the reaction tube 203 (the process chamber 201) may be supplied to thereby perform the purge such that there is no adverse effect generated in Step 3a. As described above, as the inside of the process chamber 201 is not completely purged, the purge time can be reduced, thereby improving the throughput. In addition, the consumption of the N₂ gas can also be suppressed to a minimal necessity.

The temperature of the heater 207 at this time is set such that the temperature of the wafer 200 falls within a range of, for example, 350 to 800 degrees C., more specifically, 450 to 800 degrees C., or further more specifically, 550 to 750 degrees C., in the same manner as when the HCDS gas is supplied. A supply flow rate of the N₂ gas, as a purge gas, supplied from each inert gas supply system is set to fall within a range of, for example, (100 to 2,000 sccm (0.1 to 2 slm). The purge gas may include a rare gas such as an Ar gas, a He gas, a Ne gas, a Xe gas, and the like, in addition to the N₂ gas.

### [Step 3a]

After the residual gas is removed from the process chamber 201, the valve 243d is opened to flow the O₂ gas into the gas supply pipe 232d. A flow rate of the O₂ gas flowing into the gas supply pipe 232d is adjusted by the MFC 241d. The flow rate-adjusted O₂ gas passes through the gas supply pipe 232c and is supplied into the buffer chamber 237, which is kept in the heated and depressurized state, through the gas supply holes 248c of the nozzle 233c. At the same time, the valve 243e is opened to flow the H₂ gas into the gas supply pipe 232e. A flow rate of the H₂ gas flowing into the gas supply pipe 232e is adjusted by the MFC 241e. The flow rate-adjusted H₂ gas passes through the gas supply pipe 232c, and is supplied into the buffer chamber 237, which is kept in the heated and depressurized state, through the gas supply holes 248c of the nozzle 233c. In addition, when passing through the gas supply pipe 232c, the H₂ gas is mixed with the O₂ gas in the gas supply pipe 232c. That is, the mixed gas of the O₂ gas and the H₂ gas is supplied through the nozzle 233c. The mixed gas of the O₂ gas and the H₂ gas supplied into the buffer chamber 237 is supplied into the process chamber 201, which is kept in the heated and depressurized state, through the gas supply holes 248d of the buffer chamber 237 and exhausted through the exhaust pipe 231 (O₂ gas+H₂ gas supply).

At the same time, the N₂ gas may be supplied from the inert gas supply pipe 232i by opening the valve 243i. A flow rate of the N₂ gas is adjusted by the MFC 241i, and the N₂ gas is supplied into the gas supply pipe 232d. Also, the N₂ gas may be supplied from the inert gas supply pipe 232j by opening the valve 243j. A flow rate of the N₂ gas is adjusted by the MFC 241j, and the N₂ gas is supplied into the gas supply pipe 232e. In this case, the mixed gas of the O₂ gas, the H₂ gas and the N₂ gas is supplied from the nozzle 233c. In addition, the inert gas may include a rare gas such as an Ar gas, a He gas, a Ne gas, a Xe gas, and the like, in addition to the N₂ gas. Here, in order to prevent infiltration of the O₂ gas and the H₂ gas into the nozzles 233a, 233b and 233d or an upstream side of the gas supply pipe 232c, the valves 243f to 243h and 243m are opened to flow the N₂ gas into the inert gas supply pipes 232f to 232h and 232m. The N₂ gas is supplied into the process chamber 201 through the gas supply pipes 232a, 232b, 232c and 232l, the nozzles 233a to 233d, and the buffer chamber 237 and exhausted through the exhaust pipe 231.

At this time, the APC valve 244 is appropriately adjusted so that the internal pressure of the process chamber 201 is maintained at a pressure less than atmospheric pressure, for example, within a range of 1 to 1,000 Pa. A supply flow rate of the O₂ gas controlled by the MFC 241d is set to fall within a range of, for example, 1,000 to 10,000 sccm (1 to 10 slm). A supply flow rate of the H₂ gas controlled by the MFC 241e is set to fall within a range of, for example, 1,000 to 10,000 sccm (1 to 10 slm). A supply flow rate of the N₂ gas controlled by each of the MFCs 241f to 241j and 241m is set to fall within a range of, for example, 100 to 2,000 sccm (0.1 to 2 slm). In addition, a time of supplying the O₂ gas and the H₂ gas to the wafer 200, i.e. a gas supply time (irradiation time), is set to fall within a range of, for example, 1 to 120 seconds. The temperature of the heater 207 is set such that the temperature of the wafer 200 falls within the same range as when the HCDS gas is supplied in Step 1a and falls within a temperature range in which an improved oxidizing power effect described later becomes remarkable, i.e., for example, 450 to 800 degrees C., or specifically, 550 to 750 degrees C. In addition, it was confirmed that the improved oxidizing power effect (described later) caused by the addition of the H₂ gas to the O₂ gas under a depressurized state became remarkable if the temperature fell within such a range. It was also confirmed that the improved oxidizing power effect could not be obtained if the temperature of the wafer 200 was too low. Considering the throughput, in this way, it is preferred that the temperature of the heater 207 be set such that the internal temperature of the process chamber 201 is maintained within the same temperature range in Steps 1a to 3a. Further, it is more preferred that the temperature of the heater 207 be set such that the internal temperature of the process chamber 201 is maintained within the same temperature range over Steps 1a to 4a (described later). In this case, the temperature of the heater 207 is set such that the internal temperature of the process chamber 201 is fixed within a range of, for example, 450 to 800 degrees C., or specifically, 550 to 750 degrees C., over Steps 1a to 4a (described later).

As the O₂ gas and the H₂ gas are supplied into the process chamber 201 under the above-described condition, the O₂ gas and the H₂ gas are thermally activated under non-plasma conditions and a heated and depressurized atmosphere and react with each other, thereby producing a moisture (H₂O)-free oxidizing species containing oxygen such as atomic oxygen (O). In addition, mainly with the oxidizing species, oxidation processing is performed on the silicon-containing layer formed on the wafer 200 in Step 1a. Then, this oxidation processing causes the silicon-containing layer to be changed (modified) into a silicon oxide layer (SiO₂ layer, hereinafter, simply also referred to as an SiO layer). In this way, according to the oxidation processing, it is possible to drastically improve the oxidizing power as compared with the sole supply of the O₂. That is, as the H₂ gas is added to the O₂ gas under the depressurized atmosphere, a drastically improved oxidizing power effect is obtained as compared with the sole supply of the O₂.

Here, any one or both of the O₂ gas and the H₂ gas may also be plasma-activated and flowed. As the O₂ gas and/or H₂ gas is plasma-activated and flowed, an oxidizing species containing an active species having higher energy can be produced, and by performing the oxidation processing with this oxidizing species, effects such as improved device properties may be obtained. For example, when both the O₂ gas and the H₂ gas are plasma-activated, by applying high-frequency power between the first rod-shaped electrode 269 and the second rod-shaped electrode 270 from the high-frequency power source 273 through the matcher 272, the mixed gas of the O₂ gas and the H₂ gas supplied into the buffer chamber 237 is plasma-activated (plasma-excited) to be supplied as a gas containing active species, i.e., a gas containing O₂* (active species of oxygen) or H₂* (active species of hydrogen) (oxidizing species) into the process chamber 201 through the gas supply holes 248d, and exhausted through the exhaust pipe 231. At this time, the high-frequency power applied between the first rod-shaped electrode 269 and the second rod-shaped electrode 270 from the high-frequency power source 273 is set to fall within a range of, for example, 50 to 1,000 W. The other processing conditions are set to be the same as the above-described processing conditions. Further, in the above-described temperature range, the O₂ gas and the H₂ gas are thermally activated and sufficiently react with each other, thereby producing a sufficient quantity of oxidizing species such as atomic oxygen (O). Therefore, even when the O₂ gas and the H₂ gas are thermally activated under non-plasma conditions, sufficient oxidizing power is obtained. In addition, since a soft reaction can be caused without plasma damage if the O₂ gas and the H₂ gas are activated by heat and supplied, the above-described oxidation processing can be performed softly.

The oxygen-containing gas, i.e., oxidizing gas, may include an ozone (O₃) gas and the like, in addition to the oxygen (O₂) gas. Further, as a result of a test of an adding effect of the hydrogen-containing gas to a nitrogen monoxide (NO) gas or a nitrous oxide (N₂O) gas in the above-described temperature range, it was confirmed that an effect of improved oxidizing power could not obtained as compared with the sole supply of the NO gas or N₂O gas. That is, the oxygen-containing gas preferably includes an oxygen-containing, nitrogen-free gas (gas containing oxygen and not containing nitrogen). The hydrogen-containing gas, i.e., reducing gas, may include a deuterium (D₂) gas and the like, in addition to the hydrogen (H₂) gas. In addition, if an ammonia (NH₃) gas, a methane (CH₄) gas or the like is used, nitrogen (N) impurities or carbon (C) impurities may be added to a film. In some embodiments, the hydrogen-containing gas may include a hydrogen-containing, other-element-free gas (gas containing hydrogen or deuterium and not containing other elements). In other embodiments, the oxygen-containing gas may include at least one gas selected from a group consisting of O₂ gas and O₃ gas, and the hydrogen-containing gas may include at least one gas selected from a group consisting of H₂ gas and D₂ gas.

### [Step 4a]

After changing the silicon-containing layer into the silicon oxide layer, the valve 243d is closed to stop the supply of the O₂ gas. In addition, the valve 243e is closed to stop the supply of the H₂ gas. At this time, while the APC valve 244 of the exhaust pipe 231 is in an open state, the inside of the process chamber 201 is vacuum exhausted by the vacuum pump 246, and the O₂ gas or the H₂ gas remaining in the process chamber 201 which does not react or remains after contributing to the formation of the silicon oxide layer or reaction byproducts are removed from the process chamber 201. In addition, the valves 243f to 243g and 243m are in an open state, and the supply of the N₂ gas into the process chamber 201 is maintained. The N₂ gas acts as a purge gas, and thus, the O₂ gas or the H₂ gas remaining in the process chamber 201 which does not react or remains after contributing to the formation of the silicon oxide layer or reaction byproducts can be more effectively removed from the process chamber 201 (residual gas removal).

Moreover, in this case, the gas remaining in the process chamber 201 may not be completely removed, and the inside of the process chamber 201 may not be completely purged. When the gas remaining in the process chamber 201 is very small in amount, there is no adverse effect generated in Step 1a performed thereafter. Here, the amount of the N₂ gas supplied into the process chamber 201 need not be large, and for example, approximately the same amount of the N₂ gas corresponding to the volume of the reaction tube 203 (the process chamber 201) may be supplied to thereby perform the purge such that there is no adverse effect generated in Step 1a. As described above, as the inside of the process chamber 201 is not completely purged, the purge time can be reduced, thereby improving the throughput. In addition, the consumption of the N₂ gas can also be suppressed to a minimal necessity.

The temperature of the heater 207 at this time is set such that the temperature of the wafer 200 falls within a range of, for example, 450 to 800 degrees C., or specifically, 550 to 750 degrees C., in the same manner as when the O₂ gas and the H₂ gas are supplied. A supply flow rate of the N₂ gas, as a purge gas, supplied from each inert gas supply system is set to fall within a range of, for example, 100 to 2,000 sccm (0.1 to 2 slm). The purge gas may include a rare gas such as an Ar gas, a He gas, a Ne gas, a Xe gas, and the like, in addition to the N₂ gas.

The above-described Steps 1a to 4a are set as one cycle, and the cycle is performed once or more, e.g., a plurality of times, thereby forming the first silicon oxide film having the predetermined film thickness on the wafer 200. The first silicon oxide film becomes an underlayer film of the silicon nitride film formed in the later-described process.

Then, an NH₃ gas prior supply process is performed, and after the NH₃ gas prior supply process, the process of forming the silicon nitride film is performed. The NH₃ gas prior supply process will be described later.

### (Process of Forming Silicon Nitride Film)

In the process of forming the silicon nitride film, the following Steps 1b to 4b are set as one cycle, and the cycle is performed once or more, thereby forming the silicon nitride film having a predetermined film thickness on the first silicon oxide film as an underlayer film. Specifically, the silicon nitride film is formed on the first silicon oxide film, the surface of which is modified into a silicon nitride layer in the NH₃ gas prior supply process described later, i.e., on a silicon nitride layer (hereinafter, also referred to as an underlayer) formed on the uppermost surface of the first silicon oxide film. However, in the following description, for convenience, the silicon nitride film or the like may be described as being formed on the first silicon oxide film. Here, not the HCDS gas used in forming the first silicon oxide film but the DCS gas having higher pyrolysis temperature and lower reactivity than the HCDS gas is used as the second precursor gas. In addition, the silicon nitride film is formed while the temperature of the wafer 200 is maintained such that a difference from the temperature of the wafer 200 in the above-described process of forming the first silicon oxide film falls within a range less than 150 degrees C., or specifically, less than 100 degrees C.

### [Step 1b]

The valve 243b is opened to flow the DCS gas into the first gas supply pipe 232b. A flow rate of the DCS gas flowing into the first gas supply pipe 232b is adjusted by the MFC 241b. The flow rate-adjusted DCS gas is supplied into the process chamber 201, which is kept in the heated and depressurized state, through the gas supply holes 248a of the nozzle 233b and exhausted through the exhaust pipe 231 (DCS gas supply).

At the same time, the N₂ gas may be supplied from the inert gas supply pipe 232g by opening the valve 243g. A flow rate of the N, gas is adjusted by the MFC 241g, and the N₂ gas is supplied into the gas supply pipe 232b. The flow rate-adjusted N₂ gas is mixed with the flow rate-adjusted DCS gas in the gas supply pipe 232b, and the mixed gas is supplied into the process chamber 201, which is kept in the heated and depressurized state, through the gas supply holes 248b of the nozzle 233b and exhausted through the exhaust pipe 231. Here, in order to prevent infiltration of the DCS gas into the buffer chamber 237 or the nozzles 233a, 233c and 233d, the valves 243f, 243h, 243i, 243j and 243m are opened to flow the N₂ gas into the inert gas supply pipes 232f, 232h, 232i, 232j and 232m. The N₂ gas is supplied into the process chamber 201 through the gas supply pipes 232a, 232c, 232d, 232e and 232l, the nozzles 233a, 233c and 233d, and the buffer chamber 237 and exhausted through the exhaust pipe 231.

At this time, the APC valve 244 is appropriately adjusted so that the internal pressure of the process chamber 201 is maintained at a pressure less than atmospheric pressure, for example, within a range of 10 to 1,000 Pa. A supply flow rate of the DCS gas controlled by the MFC 241b is set to fall within a range of, for example, 10 to 1,000 sccm (0.01 to 1 slm). A supply flow rate of the N₂ gas controlled by each of the MFCs 241f to 241j and 243m is set to fall within a range of, for example, 100 to 2,000 sccm (0.1 to 2 slm). A time of supplying the DCS gas to the wafer 200, i.e., a gas supply time (irradiation time), is set to fall within a range of, for example, 1 to 120 seconds. A temperature of the heater 207 is set such that a CVD reaction occur within the process chamber 201 in the above-described pressure range. That is, the temperature of the heater 207 is set such that a temperature of the wafer 200 falls within a range of, for example, 550 to 800 degrees C., more specifically, 600 to 800 degrees C., or further more specifically, 650 to 750 degrees C. In addition, when the temperature of the wafer 200 is less than 550 degrees C., it becomes difficult for the DCS to be decomposed and adsorbed onto the wafer 200. Further, when the temperature of the wafer 200 is less than 600 degrees C., the decomposition and adsorption of the DCS is not sufficiently performed, so that it may be difficult to obtain a practical film forming rate. Also, if the temperature of the wafer 200 is equal to or higher than 650 degrees C. the decomposition and adsorption of the DCS is sufficiently performed, thereby obtaining a practically sufficient film forming rate. Further, when the temperature of the wafer 200 exceeds 750 degrees C., specifically, 800 degrees C., the film thickness uniformity is remarkably deteriorated as a CVD reaction is strengthened. Accordingly, the temperature of the wafer 200 may be set to fall within a range of, for example, 550 to 800 degrees C., more specifically, 600 to 800 degrees C., or further more specifically, 650 to 750 degrees C. In addition, although the temperature of the wafer 200 may be the same as the temperature of the wafer 200 in the process of forming the first silicon oxide film, a different temperature is also possible. For example, as in the embodiment, when the HCDS gas is used in the process of forming the first silicon oxide film and the DCS gas having lower reactivity than the HCDS gas is used in the process of forming the silicon nitride film, it may be preferred in some cases that the temperature of the wafer 200 in the process of forming the silicon nitride film (second temperature) is set to be higher than the temperature of the wafer 200 in the process of forming the first silicon oxide film (first temperature). In this case, in order to prevent the throughput from being deteriorated, a difference between the first temperature and the second temperature is made to fall within a range less than 150 degrees C., or more specifically, less than 100 degrees C. For example, the first temperature may fall within a range of 550 to 600 degrees C., and the second temperature may fall within a range of 650 to 700 degrees C.

As the DCS gas is supplied into the process chamber 201 under the above-described conditions, i.e., the condition where a CVD reaction occurs, a silicon-containing layer having a thickness of, for example, less than one atomic layer to several atomic layers is formed on the first silicon oxide film (underlayer). The silicon-containing layer may be an adsorption layer of the DCS gas, a silicon layer (Si layer), or both of these. However, it is preferred that the silicon-containing layer be a Si and Cl-containing layer.

Here, the silicon layer is a generic name including a discontinuous layer in addition to a continuous layer formed of Si, or a silicon thin film formed by laminating them. Also, a continuous layer formed of Si may be referred to as the silicon thin film. In addition, Si constituting the silicon layer includes Si, in which bonding to Cl or H is not completely broken.

Moreover, the adsorption layer of the DCS gas may include a chemisorption layer in which gas molecules of the DCS gas are discontinuous, in addition to a chemisorption layer in which the gas molecules of the DCS gas are continuous. That is, the adsorption layer of the DCS gas may include an adsorption layer that contains DCS molecules having a thickness of one molecular layer or less. Further, DCS (SiH₂Cl₂) molecules constituting the chemisorption layer of the DCS gas also contains molecules in which bonding of Si and Cl or bonding of Si and H is partially broken (SiHₓCl_{y} molecules). That is, the chemisorption layer of the DCS gas includes a chemisorption layer in which SiH₂Cl₂ molecules and/or SiHₓCl_{y} molecules are continuous or a chemisorption layer in which Si₂Cl₆ molecules and/or SiₓCl_{y} molecules are discontinuous.

Under a condition in which the DCS gas is autolyzed (pyrolyzed), i.e. under a condition in which a pyrolysis reaction of the DCS gas occurs, the silicon layer is formed by depositing Si on the first silicon oxide film (underlayer). Under a condition in which the DCS gas is not autolyzed (pyrolyzed), i.e., under a condition in which a pyrolysis reaction of the DCS gas does not occur, the adsorption layer of the DCS gas is formed by adsorbing the DCS gas onto the first silicon oxide film (underlayer). The formation of the silicon layer on the wafer 200 results in a higher film forming rate than the formation of the adsorption layer of the DCS gas on the first silicon oxide film (underlayer).

When the thickness of the silicon-containing layer formed on the first silicon oxide film (underlayer) exceeds several atomic layers, an effect of the nitriding (modification) reaction in Steps 3b described later does not reach the entire silicon-containing layer. In addition, a minimum value of the thickness of the silicon-containing layer that can be formed on the first silicon oxide film (underlayer) is less than one atomic layer. Accordingly, the thickness of the silicon-containing layer may range from less than one atomic layer to several atomic layers. When the thickness of the silicon-containing layer is one atomic layer or less (i.e., one atomic layer or less than one atomic layer), an effect of the nitriding (modification) reaction in Step 3b described later can be relatively increased, and thus a time required for the nitriding (modification) reaction in Step 3b can be reduced. That is, it is possible to efficiently perform the nitriding of the silicon-containing layer in Step 3b. In addition, a time required for forming the silicon-containing layer in Step 1a can also be reduced. As a result, a processing time per one cycle can be reduced, and a total processing time can also be reduced. That is, the film forming rate can be increased. In addition, as the thickness of the silicon-containing layer is one atomic layer or less, it may become easier to maintain and control the film thickness uniformity.

The second precursor gas (second silicon-containing gas) may include not only an inorganic precursor such as hexachlorodisilane (Si₂Cl₆, abbreviation: HCDS) gas, a tetrachlorosilane, i.e., silicon tetrachloride (SiCl₄, abbreviation: STC) gas, a trichlorosilane (SiHCl₃, abbreviation: TCS) gas, a dichlorosilane (SiH₂Cl₂, abbreviation: DCS) gas, a monochlorosilane (SiH₃Cl, abbreviation: MCS) gas, a monosilane(SiH₄) gas, or the like, in addition to the dichlorosilane (SiH₂Cl₂, abbreviation: DCS) gas, but also an organic precursor such as a tetrakis(dimethylamino)silane (Si[N(CH₃)₂]₄, abbreviation: 4DMAS) gas, a tris(dimethylamino)silane (Si[N(CH₃)₂]₃H, abbreviation: 3DMAS) gas, a bis(diethylamino)silane (Si[N(C₂H₅)₂]₂H₂, abbreviation: 2DEAS) gas, or a bis(tert-butylamino)silane (SiH₂[NH(C₄H₉)]₂, abbreviation: BTBAS) gas. The inert gas may include a rare gas such as an Ar gas, a He gas, a Ne gas, a Xe gas, and the like, in addition to the N₂ gas.

### [Step 2b]

After the silicon-containing layer is formed on the first silicon oxide film (underlayer), the valve 243b is closed to stop the supply of the DCS gas. At this time, while the APC valve 244 of the exhaust pipe 231 is in an open state, the inside of the process chamber 201 is vacuum exhausted by the vacuum pump 246, and the DCS gas remaining in the process chamber 201 which does not react or remains after contributing to the formation of the silicon-containing layer is removed from the process chamber 201. In addition, the valves 243f to 243j and 243m are in an open state, and the supply of the N₂ gas into the process chamber 201 is maintained. The N₂ gas acts as a purge gas, and thus, the DCS gas remaining in the process chamber 201 which does not react or remains after contributing to the formation of the silicon-containing layer can be more effectively removed from the process chamber 201 (residual gas removal).

Moreover, in this case, the gas remaining in the process chamber 201 may not be completely removed, and the inside of the process chamber 201 may not be completely purged. When the gas remaining in the process chamber 201 is very small in amount, there is no adverse effect generated in Step 3b performed thereafter. Here, the amount of the N₂ gas supplied into the process chamber 201 need not be large, and for example, approximately the same amount of the N₂ gas corresponding to the volume of the reaction tube 203 (the process chamber 201) may be supplied to thereby perform the purge such that there is no adverse effect generated in Step 3b. As described above, as the inside of the process chamber 201 is not completely purged, the purge time can be reduced, thereby improving the throughput. In addition, the consumption of the N₂ gas can also be suppressed to a minimal necessity.

The temperature of the heater 207 at this time is set such that the temperature of the wafer 200 falls within a range of, for example, 550 to 800 degrees C., more specifically, 600 to 800 degrees C., or further more specifically, 650 to 750 degrees C., in the same manner as when the DCS gas is supplied. A supply flow rate of the N₂ gas, as a purge gas, supplied from each inert gas supply system is set to fall within a range of, for example, 100 to 2,000 sccm (0.1 to 2 slm). The purge gas may include a rare gas such as an Ar gas, a He gas, a Ne gas, a Xe gas, and the like, in addition to the N₂ gas.

### [Step 3b]

After the residual gas is removed from the process chamber 201, the valve 243c is opened to flow the NH, gas into the gas supply pipe 232c. A flow rate of the NH₃ gas flowing into the gas supply pipe 232c is adjusted by the MFC 241c. The flow rate-adjusted NH₃ gas passes through the gas supply pipe 232c and is supplied into the buffer chamber 237, which is kept in the heated and depressurized state, through the gas supply holes 248c of the nozzle 233c. At this time, if high-frequency power is applied between the first rod-shaped electrode 269 and the second rod-shaped electrode 270, the NH₃ gas supplied into the buffer chamber 237 is plasma-activated. If no high-frequency power is applied between the first rod-shaped electrode 269 and the second rod-shaped electrode 270, the NH₃ gas supplied into the buffer chamber 237 is activated by heat. In the embodiment, the NH₃ gas supplied into the buffer chamber 237 is activated by heat by applying no high-frequency power between the first rod-shaped electrode 269 and the second rod-shaped electrode 270. Accordingly, the NH gas supplied into the buffer chamber 237 is activated by heat, supplied into the process chamber 201, which is kept in the heated and depressurized state, through the gas supply holes 248c of the buffer chamber 237 and exhausted through the exhaust pipe 231 (NH₃ gas supply). In addition, although the NH₃ gas may be plasma-activated and supplied, a soft reaction can be caused if the NH₃ gas is activated by heat and supplied, thereby making it possible to perform the nitriding described later more softly.

At the same time, the N₂ gas may be supplied from the inert gas supply pipe 232h by opening the valve 243h. A flow rate of the N₂ gas is adjusted by the MFC 241h and the N₂ gas is supplied into the gas supply pipe 232c. The flow rate-adjusted N₂ gas is mixed with the flow rate-adjusted NH₃ gas in the gas supply pipe 232c, and the mixed gas is supplied into the buffer chamber 237, which is kept in the heated and depressurized state, through the gas supply holes 248c of the nozzle 233c, supplied into the process chamber 201, which is kept in the heated and depressurized state, through the gas supply holes 248d of the buffer chamber 237, and exhausted through the exhaust pipe 231. At this time, in order to prevent infiltration of the NH₃ gas into the nozzles 233a, 233b and 233d or the gas supply pipes 232d and 232e, the valves 243f, 243g, 243i, 243j and 243m are opened to flow the N₂ gas into the inert gas supply pipes 232f, 232g, 232i, 232j and 232m. The N₂ gas is supplied into the process chamber 201 through the gas supply pipes 232a, 232b, 232d, 232e and 232l, the nozzles 233a to 233d, and the buffer chamber 237 and exhausted through the exhaust pipe 231.

At this time, the APC valve 244 is appropriately adjusted, so that the internal pressure of the process chamber 201 is maintained at a pressure less than atmospheric pressure, for example, within a range of 1 to 3,000 Pa. A supply flow rate of the NH₃ gas controlled by the MFC 241c is set to fall within a range of, for example, 100 to 10,000 (sccm (0.1 to 10 slm). A supply flow rate of the N₂ gas controlled by each of the MFCs 241f to 241j and 243m is set to fall within a range of, for example, 100 to 2,000 sccm (0.1 to 2 slm). A time of exposing the NH₃ gas to the wafer 200 is set to fall within a range of, for example, 1 to 120 seconds. The temperature of the heater 207 is set such that the temperature of the wafer 200 falls within the same range as when the DCS gas is supplied in Step 1b, i.e., for example, 550 to 800 degrees C. more specifically, 600 to 800 degrees C., or further more specifically, 650 to 750 degrees C. In addition, it was confirmed that a nitriding effect (described later) caused by the NH₃ gas, i.e., a nitriding reaction of the silicon-containing layer, was obtained under a depressurized atmosphere if the temperature fell within such a range. It was also confirmed that the nitriding effect could not be obtained if the temperature of the wafer 200 was too low. Considering the throughput, as described above, it is preferred that the temperature of the heater 207 be set such that the internal temperature of the process chamber 201 is maintained at the same temperature range in Steps 1b to 3b. Further, as described above, it is more preferred that the temperature of the heater 207 be set such that the internal temperature of the process chamber 201 is maintained within the same temperature range over Steps 1b to 4b (described later).

As the NH₃ gas is supplied into the process chamber 201 under the above-described condition, the NH₃ gas is thermally activated under non-plasma conditions and a heated and depressurized atmosphere, or pyrolyzed, thereby generating a nitride species containing nitrogen. At this time, since no DCS gas is flowed into the process chamber 201, the NH₃ gas does not cause a gas phase reaction, but the nitride species obtained by thermally activating or pyrolyzing the NH₃ gas reacts with at least a portion of the silicon-containing layer formed on the first silicon oxide film (underlayer) in Step 1b. Accordingly, the nitriding processing is performed on the silicon-containing layer, and the nitriding processing causes the silicon-containing layer to be changed (modified) into the silicon nitride layer (Si₃N₄ layer, hereinafter, also simply referred to as an SiN layer).

At this time, as described above, the NH₃ gas may be plasma-activated and flowed. As the NH₃ gas is plasma-activate and flowed, a nitride species containing an active species having higher energy may be generated, and by performing the nitriding processing with this nitride species, effects such as improved device properties may be obtained. When the NH₃ gas is plasma-activated, by applying high-frequency power between the first rod-shaped electrode 269 and the second rod-shaped electrode 270 from the high-frequency power source 273 through the matcher 272, the NH₃ gas supplied into the buffer chamber 237 is plasma-activated (plasma-excited) to be supplied as a gas containing NH₃* (active species of ammonia) (nitride species) into the process chamber 201 through the gas supply holes 248d, and exhausted through the exhaust pipe 231. At this time, the high-frequency power applied between the first rod-shaped electrode 269 and the second rod-shaped electrode 270 from the high-frequency power source 273 is set to be a power of, for example, 50 to 1,000 W. The other processing conditions are set to be the same as the above-described processing conditions. Further, in the above-described temperature range, the NH₃ gas is sufficiently activated by heat, thereby producing a sufficient quantity of nitride species. Therefore, even when the NH₃ gas is thermally activated under non-plasma conditions, sufficient nitriding power is obtained. In addition, since a soft reaction can be caused without plasma damage if the NH₃ gas is activated by heat and supplied, the above-described nitriding processing can be performed softly.

The nitrogen-containing gas may include a diazene (N₂H₂) gas, a hydrazine (N₂H₄) gas, a N₃H₈ gas, an amine-based gas and the like, in addition to the NH₃ gas.

### [Step 4b]

After changing the silicon-containing layer into the silicon nitride layer, the valve 243c is closed to stop the supply of the NH₃ gas. At this time, while the APC valve 244 of the exhaust pipe 231 is in an open state, the inside of the process chamber 201 is vacuum exhausted by the vacuum pump 246, and the NH₃ gas remaining in the process chamber 201 which does not react or remains after contributing to the formation of the silicon nitride layer or reaction byproducts are removed from the process chamber 201. In addition, the valves 243f to 243j and 243m are in an open state, and the supply of the N₂ gas into the process chamber 201 is maintained. The N₂ gas acts as a purge gas, and thus, the NH₃ gas remaining in the process chamber 201 which does not react or remains after contributing to the formation of the silicon nitride layer or reaction byproducts can be more effectively removed from the process chamber 201 (residual gas removal).

Moreover, in this case, the gas remaining in the process chamber 201 may not be completely removed, and the inside of the process chamber 201 may not be completely purged. When the gas remaining in the process chamber 201 is very small in amount, there is no adverse effect generated in Step 1b performed thereafter. Here, the amount of the N₂ gas supplied into the process chamber 201 need not be large, and for example, approximately the same amount of the N₂ gas corresponding to the volume of the reaction tube 203 (the process chamber 201) may be supplied to thereby perform the purge such that there is no adverse effect generated in Step 1b. As described above, as the inside of the process chamber 201 is not completely purged, the purge time can be reduced, thereby improving the throughput. In addition, the consumption of the N₂ gas can also be suppressed to a minimal necessity.

The temperature of the heater 207 at this time is set such that the temperature of the wafer 200 falls within a range of, for example, 550 to 800 degrees C., more specifically, 600 to 800 degrees C. or further more specifically, 650 to 750 degrees C., in the same manner as when the NH₃ gas is supplied. A supply flow rate of the N₂ gas, as a purge gas, supplied from each inert gas supply system is set to fall within a range of, for example, 100 to 2,000 sccm (0.1 to 2 sim). The purge gas may include a rare gas such as an Ar gas, a He gas, a Ne gas, a Xe gas, and the like, in addition to the N₂ gas.

The above-described Steps 1b to 4b are set as one cycle, and the cycle is performed once or more, e.g., a plurality of times, thereby forming the silicon nitride film having the predetermined film thickness on the first silicon oxide film as the underlayer film, specifically, on the silicon nitride layer, which is formed on the uppermost surface of the first silicon oxide film in the NH₃ gas prior supply process. The silicon nitride film becomes an underlayer film of the second silicon oxide film formed in the later-described process.

### (Process of Forming Second Silicon Oxide Film)

Next, the following Steps 1c to 4c are set as one cycle, and the cycle is performed once or more, thereby forming the second silicon oxide film having a predetermined film thickness on the silicon nitride film as an underlayer film.

Steps 1c to 4c are performed in the same sequence and condition as Steps 1a to 4a of the above-described process of forming the first silicon oxide film. That is, when the second silicon oxide film is formed, the first precursor gas, i.e. the HCDS gas used in the process of forming the first silicon oxide film is used as the precursor gas. In addition, the second silicon oxide film is formed while the temperature of the wafer 200 is maintained so as to fall within the same temperature range as the temperature range of the wafer 200 in the above-described process of forming the first silicon oxide film.

Then, Steps 1c to 4c are set as one cycle, and the cycle is performed once or more, e.g., a plurality of times, thereby forming the second silicon oxide film having the predetermined film thickness on the silicon nitride film. As a result, the insulating film having the ONO stack structure made up by stacking the first silicon oxide film, the silicon nitride film, and the second silicon oxide film in this order is formed on the wafer 200.

### (Purge and Return to Atmospheric Pressure)

If the insulating film having the ONO stack structure is formed, the valves 243f to 243j and 243m are opened to supply the N₂ gas as the inert gas into the process chamber 201 from the respective inert the gas supply pipes 232f to 232j and 232m and exhausted through the exhaust pipe 231. The N₂ gas acts as a purge gas, and thus, the inside of the process chamber 201 is purged with the inert gas, so that the gas remaining in the process chamber 201 or reaction byproducts are removed from the process chamber 201 (purge). Thereafter, an atmosphere in the process chamber 201 is substituted with the inert gas, and the internal pressure of the process chamber 201 returns to normal pressure (return to atmospheric pressure).

### (Boat Unloading and Wafer Discharging)

Thereafter, the seal cap 219 is lowered by the boat elevator 115 to open the lower end of the manifold 209, and the processed wafer 200 supported by the boat 217 is unloaded to the outside of the process chamber 201 through the lower end of the manifold 209 (boat unloading). Then, the processed wafer 200 is discharged from the boat 217 (wafer discharging).

### (NH₃ Gas Prior Supply Process)

In the above-described processing, if the process of forming the silicon nitride film is performed immediately after the process of forming the first silicon oxide film is performed, there may be a delay in adsorption of the second precursor gas onto the surface of the first silicon oxide film or in deposition of Si onto the surface of the first silicon oxide film (so-called an incubation time) in the initial stage of forming the silicon nitride film. That is, if there is a delay in forming the silicon nitride film at its beginning stage, the productivity when forming the insulating film having the ONO stack structure may decrease. For example, when the DCS gas having higher pyrolysis temperature and lower reactivity than the HCDS gas is used as the second precursor gas for forming the silicon nitride film, even though Step 1b of the process of forming the silicon nitride film has begun, the DCS gas may not be immediately chemisorbed onto the surface of the first silicon oxide film, or Si may not be immediately deposited thereon, so that the above-described incubation time may be increased. Therefore, in the embodiment, after the process of forming the first silicon oxide film is performed, the NH₃ gas as the nitrogen-containing gas is supplied to the wafer 200 in the process vessel before the process of forming the silicon nitride film is performed. Hereinafter, a process of supplying the NH₃ gas before the process of forming the silicon nitride film (NH₃ gas prior supply process) will be described.

In the NH₃ gas prior supply process according to the embodiment, the later-described Steps 1d and 2d are performed in this order, thereby performing the nitriding process on the surface of the first silicon oxide film to form a layer having Si—N bonding as a seed layer, i.e., a silicon nitride layer on the surface of the first silicon oxide film.

### [Step 1d]

After the first silicon oxide film is formed on the wafer 200, according to the same sequence as Step 3b of the process of forming the silicon nitride film, the NH₃ gas (or the mixed gas of NH₃ gas and N₂ gas) is supplied into the process chamber 201, which is kept in the heated and depressurized state, and exhausted (NH₃ gas supply). A nitride species obtained by thermally activating or pyrolyzing the NH₃ gas reacts with the surface of the first silicon oxide film. Accordingly, nitriding (thermal nitriding) processing is performed on the surface of the first silicon oxide film, and the nitriding processing causes the surface of the first silicon oxide film to be changed (modified) into the layer having Si—N bonding, i.e., the silicon nitride layer.

### [Step 2d]

After the surface of the first silicon oxide film is changed into the silicon nitride layer, according to the same sequence as Step 4b of the process of forming the silicon nitride film, the NH₃ gas or reaction byproducts are removed from the inside of the process chamber 201, and the inside of the process chamber 201 is purged with the N₂ gas (residual gas removal).

By performing the above-described Steps 1d and 2d, the silicon nitride layer having a predetermined thickness may be formed on the first silicon oxide film as an underlayer film. Thereafter, the above-described process of forming the silicon nitride film, and the above-described process of forming the second silicon oxide film are performed in this order, so that the insulating film having the ONO stack structure made up by stacking the first silicon oxide film, the silicon nitride film, and the second silicon oxide film in this order is formed on the wafer 200.

In addition, the processing conditions of the NH₃ gas prior supply process are approximately similar to those of Steps 3b and 4b. However, the internal pressure of the process chamber 201 in Step 1d may be set to be higher than that of the process chamber 201 in Step 3b. For example, the internal pressure of the process chamber 201 may be set to fall within a range of 100 to 3,000 Pa. As the internal pressure of the process chamber 201 is set to be higher, the surface of the first silicon oxide film may be more efficiently nitrided. In addition, a time of supplying the NH₃ gas to the wafer 200, i.e., a gas supply time (irradiation time), may be set to be longer than the NH₃ gas supply time in Step 3b, for example, to fall within a range of 60 to 300) seconds. FIG. 5 shows that the time of supplying the NH₃ gas to the wafer 200 in the NH₃ gas prior supply process is longer than the time of supplying the NH₃ gas to the wafer 200 in Step 3b. In addition, the temperature of the wafer 200 may be set to be not less than the temperature of the wafer 200 in Steps 1a to 4a (first temperature) and not more than the temperature of the wafer 200 in Steps 1b to 4b (second temperature). However, as the temperature of the wafer 200 is set to be similar to the temperature of the wafer 200 in Steps 1b to 4b (second temperature), the surface of the first silicon oxide film may be sufficiently modified (nitrided). In this case, since the temperature of the wafer 200) is not changed over Step 1d to 2d and Steps 1b to 4b, the productivity can be improved accordingly. That is, it is more preferred that the temperature of the wafer 200 be similar to the second temperature. In addition, the layer having Si—N bonding (silicon nitride layer) formed on the first silicon oxide film in the NH₃ gas prior supply process may have a thickness in a range of, for example, 0.1 to 2 nm, or specifically, 1 to 2 nm.

In the embodiment, the silicon nitride layer formed on the surface of the first silicon oxide film in the NH₃ gas prior supply process acts as a layer promoting chemisorption of the second precursor gas onto the first silicon oxide film or deposition of Si thereon. That is, the silicon nitride layer formed on the surface of the first silicon oxide film acts as an initial layer, i.e., a seed layer, which promotes growth of the silicon nitride film in the initial stage of forming the silicon nitride film. As a result, even when the DCS gas or the like having higher pyrolysis temperature and lower reactivity than the HCDS gas is used as the second precursor gas, the formation of the silicon nitride film can be rapidly begun (the incubation time can be reduced), and thus the productivity when the insulating film having the ONO stack structure is formed can be more improved.

### (3) Cleaning Process

Then, a cleaning process of cleaning the inside of the process chamber 201 will be described. If the process of forming the insulating film having the ONO stack structure on the substrate is repeated, deposits including the stacked film (ONO film or the like) of the SiO films or the like as oxide films and the SiN film or the like as a nitride film or SiN-free deposits containing SiO adhere to the inside of the process chamber 201. e.g., the inner wall of the reaction tube 203, the inner wall of the manifold 209, and the like. Further, in the embodiment, the inside of the process chamber 201 is cleaned before a thickness of the deposits adhering to the inner wall of the reaction tube 203 and the like reaches a predetermined level before the deposits are peeled off and falls.

In the embodiment, the cleaning process includes: a process of supplying a hydrogen-free fluorine-based gas from the nozzles 233a and 233b, as first nozzles, which are installed in the manifold 209 to extend upward from the manifold 209 to the inside of the reaction tube 203, at least to the inner wall of the reaction tube 203, and a process of supplying a hydrogen fluoride gas from the nozzle 233d, as a second nozzle, which is installed in the manifold 209, at least to the inner wall of the manifold 209.

Further, in the embodiment, in the process of supplying the hydrogen-free fluorine-based gas, the deposits including the stacked film of the oxide and nitride films adhering to a first portion including the inner wall of the reaction tube 203 may be removed, and in the process of supplying the hydrogen fluoride gas, the deposits including the oxide film adhering to a second portion, including the inner wall of the manifold 209, which has a lower temperature than the first portion when the stacked film is formed, may be removed.

Here, the first portion is a portion which has a higher temperature than the second portion when the stacked film is formed. The first portion includes the inner wall of the reaction tube 203. The deposits including the stacked film (ONO film or the like) of the SiO films or the like as oxide films and the SiN film or the like as a nitride film adhere to the first portion when the stacked film is formed. In some cases, the deposits including the stacked film (ONO film or the like) of the SiO films or the like and the SiN film or the like may adhere to an upper portion of the inner wall of the manifold 209 as well as the inner wall of the reaction tube 203. Therefore, the upper portion of the inner wall of the manifold 209 as well as the inner wall of the reaction tube 203 may be included in the first portion.

In addition, the second portion is a portion which has a lower temperature than the first portion. The second portion includes the inner wall of the manifold 209. The deposits including the SiO film or the like as an oxide film adhere to the second portion but the SiN film or the like as a nitride film does not adhere to the second portion. That is, in the embodiment, the deposits adhering to the second portion is an SiN-free substance containing SiO. In the embodiment, the SiN-free substance containing SiO may adhere to lower portions of the nozzles 233a to 233d, a lower portion of an outer wall of the buffer chamber 237, the upper surface of the seal cap 219, a side surface of the rotary shaft 255, a side or bottom surface of the heat insulating member 218, and the like, as well as the inner wall of the manifold 209. Accordingly, in the embodiment, these portions may be included in the second portion.

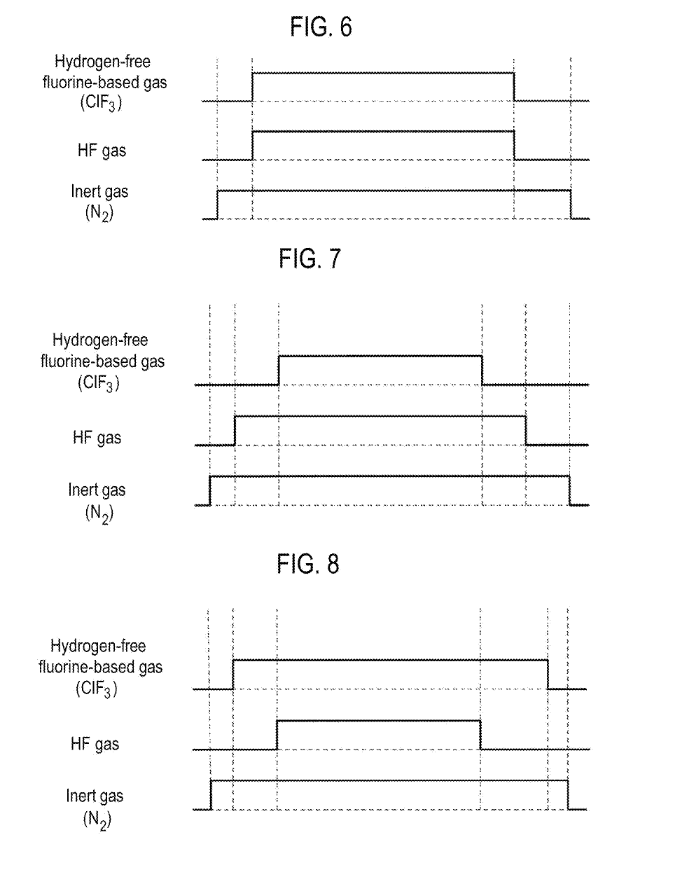

Hereinafter, the cleaning process will be described with reference to FIG. 6. Further, in the following description, operations of the respective parts constituting the substrate processing apparatus are controlled by the controller 121. Here, an example in which the chlorine trifluoride (ClF₃) gas as the hydrogen-free fluorine-based gas as a first cleaning gas, the hydrogen fluoride (HF) gas as a second cleaning gas, and the N₂ gas as the diluent gas or purge gas are used to remove the deposits including the stacked film (ONO film or the like) of SiO and SiN adhering to the inside of the process chamber 201, or the SiN-free deposits including SiO under a non-plasma atmosphere by thermal etching will be described.

### (Boat Loading)

The empty boat 217, i.e., the boat 217 on which the wafer 200 is not charged, is raised by the boat elevator 115 to be loaded into the process chamber 201 (boat loading). In this state, the seal cap 219 seals the lower end of the manifold 209 via the O-ring 220.

### (Pressure Adjustment and Temperature Adjustment)

The inside of the process chamber 201 is vacuum exhausted by the vacuum pump 246 to a desired pressure (vacuum level). Here, the internal pressure of the process chamber 201 is measured by the pressure sensor 245, and the APC valve 244 is feedback-controlled based on the measured pressure information. Also, the vacuum pump 246 is maintained at a regular operation state at least until the cleaning processing is terminated. Further, the process chamber 201 is heated by the heater 207 to a desired temperature. Here, an electrical conduction state to the heater 207 is feedback-controlled based on the temperature information detected by the temperature sensor 263 until the inside of the process chamber 201 reaches a desired temperature distribution. In addition, the heating of the inside of the process chamber 201 by the heater 207 is continuously performed at least until the cleaning processing is terminated. If the internal pressure and the internal temperature of the process chamber 201 respectively reach predetermined levels, the control is performed so as to maintain the pressure and the temperature at the predetermined levels. Next, the boat 217 is rotated by the rotary mechanism 267. Furthermore, the rotation of the boat 217 by the rotary mechanism 267 is continuously performed at least until the cleaning processing is terminated. Also, the boat 217 may not be rotated.

### (Cleaning Process)

Then, in a state where the internal pressure and the internal temperature of the process chamber 201 are respectively maintained at the predetermined levels, the valve 243k is opened to flow the ClF₃ gas into the gas supply pipe 232k. A flow rate of the ClF₃ gas flowing into the gas supply pipe 232k is adjusted by the MFC 241k. The flow rate-adjusted ClF₃ gas flows in the gas supply pipes 232a and 232b. The ClF₃ gas flowing in the gas supply pipe 232a is supplied into the process chamber 201 through the gas supply holes 248a of the nozzle 233a and exhausted through the exhaust pipe 231. The ClF₃ gas flowing in the gas supply pipe 232b is supplied into the process chamber 201 through the gas supply holes 248b of the nozzle 233b and exhausted through the exhaust pipe 231 (ClF₃ gas supply).

Before the valve 243k is opened, first, the N₂ gas as the inert gas may be supplied into the inert gas supply pipes 232f and 232g by opening the valves 243f and 243g, respectively. A flow rate of the N₂ gas flowing in the inert gas supply pipe 232f is adjusted by the MFC 241f. A flow rate of the N₂ gas flowing in the inert gas supply pipe 232g is adjusted by the MFC 241g. With the N₂ gas supplied, the valve 243k is opened to flow the ClF₃ gas into the gas supply pipes 232k, 232a and 232b. Accordingly, the N₂ gas flowing in the inert gas supply pipe 232f is mixed with the ClF₃ gas in the gas supply pipe 232a, and the mixed gas is supplied into the process chamber 201 through the gas supply holes 248a of the nozzle 233a and exhausted through the exhaust pipe 231. In addition, the N₂ gas flowing in the inert gas supply pipe 232g is mixed with the ClF₃ gas in the gas supply pipe 232b, and the mixed gas is supplied into the process chamber 201 through the gas supply holes 248b of the nozzle 233b and exhausted through the exhaust pipe 231.

Instead of supplying the N₂ gas as the inert gas prior to supplying the ClF₂ gas by opening the valves 243f and 243g before opening the valve 243k, the ClF₃ gas and the N₂ gas as the inert gas may be simultaneously supplied by opening the valves 243f and 243g simultaneously with the valve 243k. In addition, the inert gas may include a rare gas such as an Ar gas, a He gas, a Ne gas, a Xe gas, and the like, in addition to the N2 gas.

Further, the valve 243l is opened simultaneously with the valve 243k to flow the HF gas into the gas supply pipe 232l. A flow rate of the HF gas flowing in the gas supply pipe 232l is adjusted by the MFC 241l. The flow rate-adjusted HF gas is flown in the gas supply pipe 232l to be supplied into the process chamber 201 through the gas supply holes 248e of the nozzle 233d, and exhausted through the exhaust pipe 231. In this way, in this embodiment, the process of supplying the ClF₃ gas as the hydrogen-free fluorine-based gas and the process of supplying the HF gas as the fluorine-based gas containing hydrogen are simultaneously performed (HF gas supply process).

The N₂ gas as the inert gas may be supplied into the inert gas supply pipe 232m by opening the valve 243m before opening the valve 243l. A flow rate of the N₂ gas flowing in the inert gas supply pipe 232m is adjusted by the MFC 241m. By opening the valve 243l with the N₂ gas supplied, the HF gas flows in the gas supply pipe 232l. Accordingly, the N₂ gas flowing in the inert gas supply pipe 232m is mixed with the HF gas in the gas supply pipe 232l, and the mixed gas is supplied into the process chamber 201 through the gas supply holes 248e of the nozzle 233d and exhausted through the exhaust pipe 231. Instead of supplying the N₂ gas as the inert gas prior to supplying the HF gas by opening the valve 243m before opening the valve 243l, the HF gas and the N₂ gas as the inert gas may be simultaneously supplied by opening the valve 243l simultaneously with the valve 243m. In addition, the inert gas may include a rare gas such as an Ar gas, a He gas, a Ne gas, a Xe gas, and the like, in addition to the N2 gas.

In this way, the ClF₃ gas is introduced into the process chamber 201 from the nozzles 233a and 233b, and the HF gas is introduced into the process chamber 201 from the nozzle 233d. When passing through the process chamber 201, the ClF₃ gas introduced into the process chamber 201 is brought into contact with the deposits including the stacked film (ONO film or the like) of SiO and SiN deposited on the inner wall of the reaction tube 203, the upper portion of the inner wall of the manifold 209, or the like, as the first portion, and at this time, the deposits are removed by a thermochemical reaction under a non-plasma atmosphere. That is, the deposits including the ONO film or the like are removed as a result of an etching reaction of the deposits and an etching species such as an active species generated by pyrolysis of the ClF₃ gas or the like. In addition, when passing through the process chamber 201, the HF gas introduced into the process chamber 201 is brought into contact with the deposits including the SiN-free substance containing SiO deposited on the inner wall of the manifold 209, the lower portions of the nozzles 233a to 233d, the lower portion of the outer wall of the buffer chamber 237, the upper surface of the seal cap 219, the side surface of the rotary shaft 255, the side or bottom surface of the heat insulating member 218, and the like, as the second portion. When the HF gas contacts the deposits, they are removed as a result of a thermochemical reaction under a non-plasma atmosphere. That is, the SiN-free deposits containing SiO are removed as a result of an etching reaction of the deposits and an etching species such as an active species generated by pyrolysis of the HF gas or the like.

In addition, since the ClF₃ gas is introduced into the process chamber 201 using the gas supply pipe 232a and the nozzle 233a used in the introduction of the HCDS gas, a substance containing the HCDS or Si decomposed from the HCDS adhering to or deposited on the insides of the gas supply pipe 232a and the nozzle 233a is removed by the ClF₃ gas. Further, since the ClF₃ gas is introduced into the process chamber 201 using the gas supply pipe 232b and the nozzle 233b used in the introduction of the DCS gas, a substance containing the DCS or Si decomposed from the DCS adhering to or deposited on the insides of the gas supply pipe 232b and the nozzle 233b is removed by the ClF₃ gas.

Conditions in the cleaning process are exemplified as follows:

Internal Temperature of Process Chamber 201: 25 to 700 degrees C., more specifically 50 to 600 degrees C.,

Internal Pressure of Process Chamber 201: 133 to 53,200 Pa (1 to 400 Torr),

Flow Rate of ClF₃ Gas: 0.1 to 5 slm,

Flow Rate of HF Gas: 0.1 to 5 slm, and

Flow Rate of N₂ Gas: 0 to 20 slm.

The cleaning is effected by etching, i.e., thermal etching with each cleaning condition (etching condition) maintained at any value within each range.

If a predetermined time of etching a thin film elapses and the cleaning of the first and second portions in the process chamber 201 is finished, the valve 243k is closed to stop the process of supplying the ClF₃ gas into the process chamber 201, and the valve 243l is closed to stop the process of supplying the HF gas into the process chamber 201. In this embodiment, the process of supplying the ClF₃ gas into the process chamber 201 and the process of supplying the HF gas into the process chamber 201 are simultaneously terminated.

### (Purge)

Even after the process of supplying the ClF₃ gas into the process chamber 201 is stopped and the process of supplying the HF gas into the process chamber 201 is stopped, the valves 243a, 243g and 243m are in an open state until after a predetermined time elapses to continue supplying the N₂ gas into the process chamber 201 from each inert gas supply system and exhaust the N₂ gas through the exhaust pipe 231, thereby removing the ClF₃ gas, the HF gas, or reaction byproducts remaining in the process chamber 201.

In some embodiments, the hydrogen-free fluorine-based gas may include a F₂ gas, a NF₃ gas, and the like, in addition to the ClF₃ gas.

### (4) Effects According to the Embodiment

According to the embodiment, it is possible to simultaneously remove the deposits including the stacked film of SiO and SiN deposited on the first portion which may reach a high temperature in the process chamber 201 and the deposits including the SiN-free substance containing SiO deposited on the second portion which may reach a low temperature in the process chamber 201. That is, it is possible to efficiently remove the different deposits deposited on these different regions (portions).

### (5) Modifications

The cleaning sequence of the embodiment may be modified, for example, as follows. Even in these modifications, the same effects as the above-described sequence can be provided. In addition, the modifications described below can be arbitrarily combined and used.

### (First Modification)

Hereinafter, a first modification will be described with reference to FIG. 7. In the cleaning sequence shown in FIG. 6, an example in which the process of supplying the ClF₃ gas as the hydrogen-free fluorine-based gas and the process of supplying the HF gas are simultaneously performed has been described. Contrarily, in the first modification, as shown in FIG. 7, the process of supplying the HF gas is initiated prior to the process of supplying the ClF₃ gas as the hydrogen-free fluorine-based gas. Further, in the first modification, the process of supplying the ClF₃ gas as the hydrogen-free fluorine-based gas is terminated prior to the termination of the process of supplying the HF gas. According to the first modification, it is possible to preferentially remove the deposits including the SiN-free substance containing SiO deposited on the second portion (which may reach a low temperature in the process chamber 201) in particular.

### (Second Modification)

Hereinafter, a second modification will be described with reference to FIG. 8. In the cleaning sequence shown in FIG. 6, an example in which the process of supplying the ClF₃ gas as the hydrogen-free fluorine-based gas and the process of supplying the HF gas are simultaneously performed has been described. Contrarily, in the second modification, as shown in FIG. 8, the process of supplying the ClF₃ gas as the hydrogen-free fluorine-based gas is initiated prior to the process of supplying the HF gas. Further, in the second modification, the process of supplying the HF gas is terminated prior to the termination of the process of supplying the ClF₃ gas. According to the second modification, it is possible to preferentially remove the deposits including the stacked film of SiO and SiN deposited on the first portion (which may reach a high temperature in the process chamber 201) in particular.

### (Third Modification)

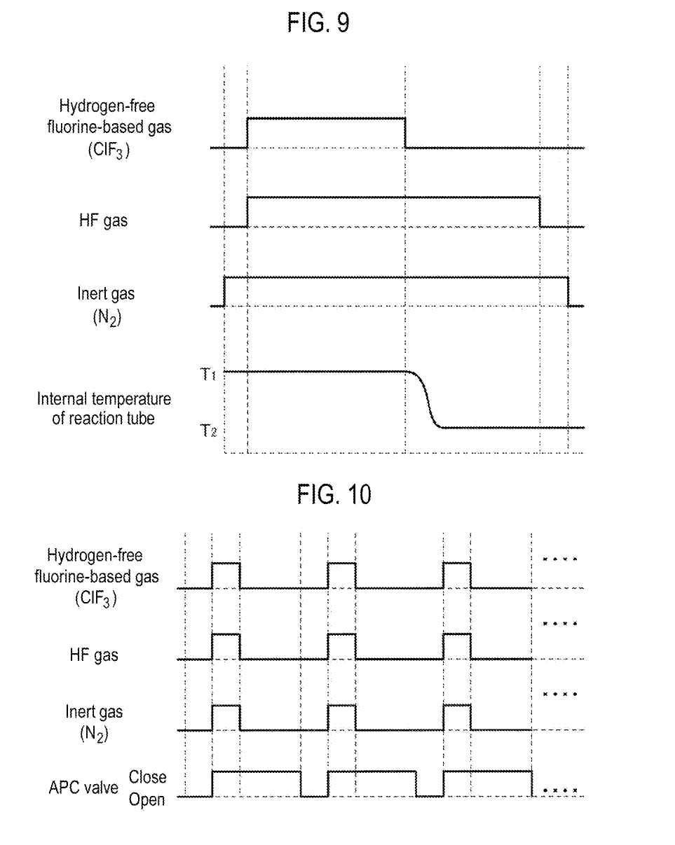

Hereinafter, a third modification will be described with reference to FIG. 9. In the third modification, as shown in FIG. 9, in a state where the internal temperature of the reaction tube 203 is set to a first temperature T1, the process of supplying the ClF₃ gas as the hydrogen-free fluorine-based gas and the process of supplying the HF gas are simultaneously performed. Thereafter, in a state where the internal temperature of the reaction tube 203 is set to a second temperature T2 lower than the first temperature T1, the process of supplying the HF gas is solely performed. In this way, even after the supply of the ClF₃ gas into the reaction tube 203 is stopped after the deposits are removed, the internal temperature of the reaction tube 203 is dropped from T1 to T2 and the supply of the HF gas into the reaction tube 203 is continued. Accordingly, since the HF gas is adsorbed, in a multi-layered fashion, onto the inner wall of the reaction tube 203 or the surface of the boat 217, which is exposed by removing the deposits including the ONO film or the like by the ClF₃ gas, it is possible to expect an effect of smoothly treating the surface of these members, i.e., the quartz members that are nonmetal members. In addition, according to the third modification, it is also possible to preferentially remove the deposits including the SiN-free substance containing SiO deposited on the second portion (which may reach a low temperature in the process chamber 201) in particular.

### (Fourth Modification)

Hereinafter, a fourth modification will be described with reference to FIG. 10. In the fourth modification, as shown in FIG. 10, the ClF₃ gas as the hydrogen-free fluorine-based gas is intermittently supplied in the process of supplying the ClF₃ gas, and the HF gas is intermittently supplied in the process of supplying the HF gas. Further, in the fourth modification, as shown in FIG. 10, an act of sealing the ClF₃ gas and the HF gas in the process chamber 201 by simultaneously performing the process of supplying the ClF₃ gas and the process of supplying the HF gas while the APC valve 244 is closed, an act of maintaining the state of the ClF₃ gas and the HF gas sealed in the process chamber 201 while the APC valve 244 is closed, and an act of exhausting the inside of the process chamber 201 while the APC valve 244 is opened are set as one cycle, and the cycle is repeated a predetermined number of times. Further in the fourth modification, as shown in FIG. 10, the APC valve 244 is closed in the act of sealing the ClF₃ gas and the HF gas in the process chamber 201 and the act of maintaining the state of the ClF₃ gas and the HF gas sealed in the process chamber 201, and the APC valve 244 is opened in the act of exhausting the inside of the process chamber 201. According to the fourth modification, since the cleaning gases (ClF₃ gas and HF gas) are not supplied into and exhausted from the process chamber 201 but are sealed in the process chamber 201 for a predetermined time, the amount of the cleaning gases contributing to thermal etching can be increased, thereby improving the cleaning efficiency. Also, the amount of the cleaning gases used can be reduced to save costs.

### (Fifth Modification)

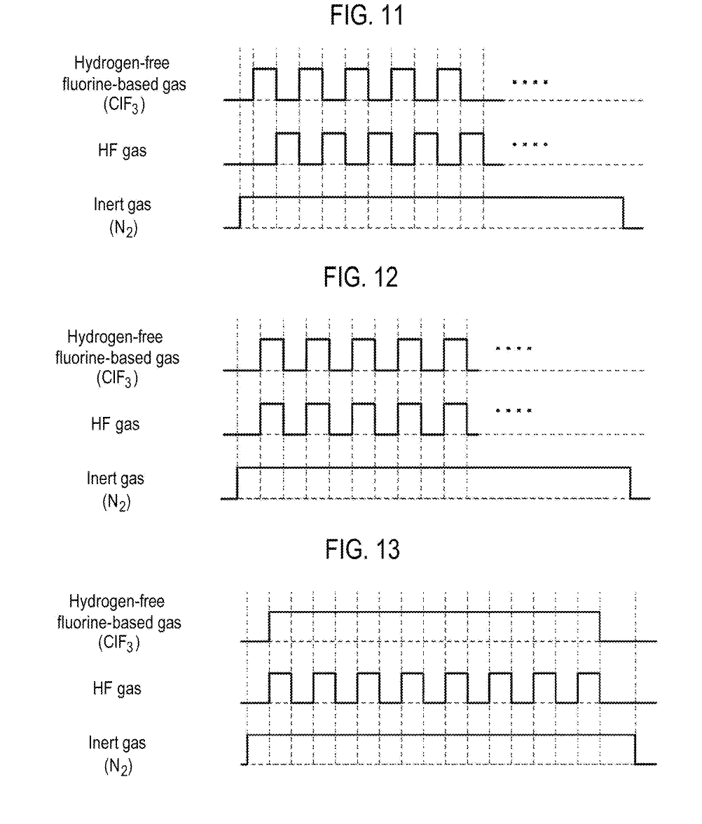

Hereinafter, a fifth modification will be described with reference to FIG. 11. In the fifth modification, as shown in FIG. 11, the ClF₃ gas as the hydrogen-free fluorine-based gas is intermittently supplied in the process of supplying the ClF₃ gas, and the HF gas is intermittently supplied in the process of supplying the HF gas. Further, in the fifth modification, as shown in FIG. 11, the process of supplying the ClF₃ gas and the process of supplying the HF gas are alternately performed. According to the fifth modification, since the ClF₃ gas and the HF gas are intermittently and alternately supplied, it is possible to improve the cleaning efficiency.

### (Sixth Modification)

Hereinafter, a sixth modification will be described with reference to FIG. 12. In the sixth modification, as shown in FIG. 12, the ClF₃ gas as the hydrogen-free fluorine-based gas is intermittently supplied in the process of supplying the ClF₃ gas, and the HF gas is intermittently supplied in the process of supplying the HF gas. Further, in the sixth modification, as shown in FIG. 12, the process of supplying the ClF₃ gas and the process of supplying the HF gas are simultaneously performed. According to the sixth modification, since the ClF₃ gas and the HF gas are intermittently supplied, it is possible to improve the cleaning efficiency.

### (Seventh Modification)

Hereinafter, a seventh modification will be described with reference to FIG. 13. In the seventh modification, as shown in FIG. 13, the ClF₃ gas as the hydrogen-free fluorine-based gas is continuously supplied in the process of supplying the ClF₃ gas, and the HF gas is intermittently supplied in the process of supplying the HF gas. According to the seventh modification, since the HF gas is intermittently supplied, it is possible to improve the cleaning efficiency.

### (Eighth Modification)

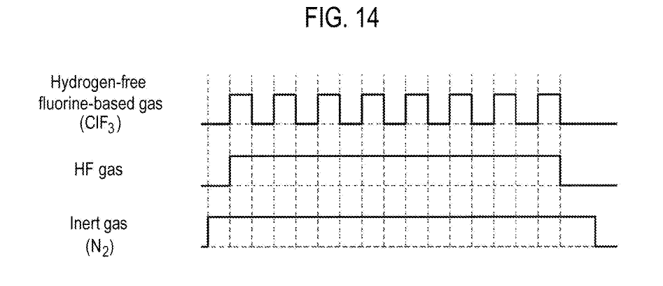

Hereinafter, an eighth modification will be described with reference to FIG. 14. In the eighth modification, as shown in FIG. 14, the ClF₃ gas as the hydrogen-free fluorine-based gas is intermittently supplied in the process of supplying the ClF₃ gas, and the HF gas is continuously supplied in the process of supplying the HF gas. According to the eighth modification, since the ClF₃ gas is intermittently supplied, it is possible to improve the cleaning efficiency.

The nozzle 233d of the embodiment may be modified as follows. In addition, the following modifications may be arbitrarily combined and used with the first to eighth modifications that are modifications of the above-described cleaning sequence.

### (Ninth Modification)

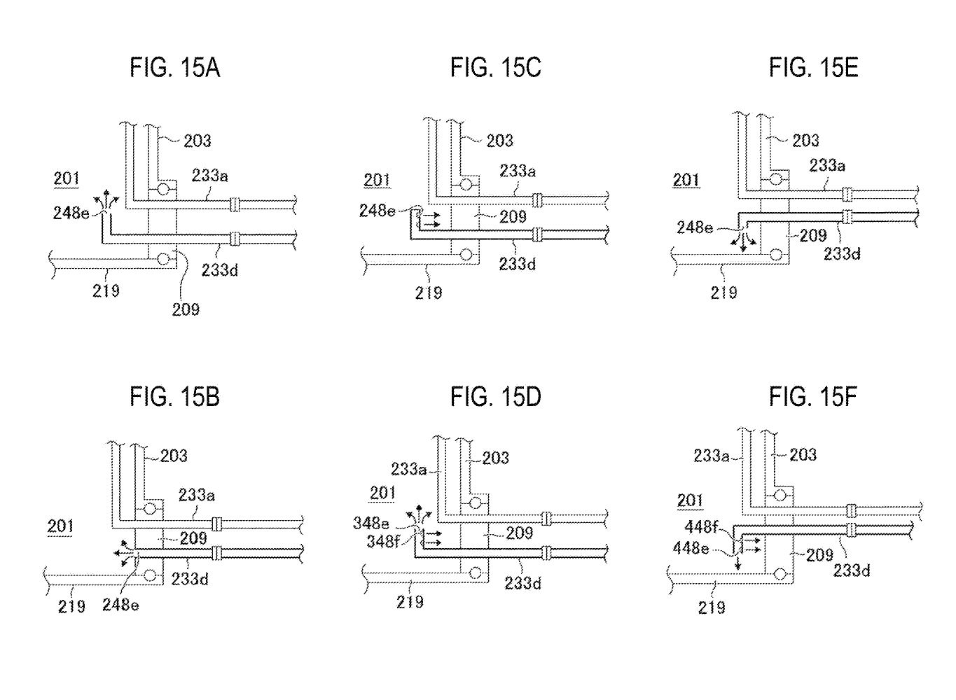

Hereinafter, a ninth modification will be described with reference to FIG. 15B. In the respective views of FIGS. 15A to 15F, among the nozzles 233a to 233d, only the nozzles 233a and 233d are shown and the nozzles 233b and 233c are not shown. In the above-described embodiment, as shown in FIG. 15A, the nozzle 233d has an L shape and has the gas supply holes 248e opened upward. Contrarily, in the ninth modification, as shown in FIG. 15B, the nozzle 233d has an L shape (short pipe shape) and has gas supply holes 248e laterally (horizontally) opened.

Further, in the ninth modification, the nozzle 233d is configured to supply the gas toward the inside portion of the process chamber 201 corresponding to the manifold 209 rather than the positions to which the nozzles 233a and 233b (see FIG. 1) supply the gases. Also, in the ninth modification, the nozzle 233d may supply the gas toward the inside of the manifold 209.

### (Tenth Modification)

Hereinafter, a tenth modification will be described with reference to FIG. 15C. As shown in FIG. 15C, in the tenth modification, the nozzle 233d is configured as an L-shaped short nozzle and has its horizontal portion installed to penetrate through the sidewall of the manifold 209 and its vertical portion installed to rise along the inner wall of the manifold 209. A plurality of gas supply holes 248e, for example, are formed in the sidewall of the vertical portion of the nozzle 233d facing the manifold 209, and the gas supply holes 248e are configured to be open toward the inner wall surface of the manifold 209. That is, in the tenth modification, the gas supply holes 248e are formed opposite to (facing) the inner wall surface of the manifold 209. In addition, the nozzle 233d is configured to supply the gas directly toward the inner wall portion of the manifold 209, in the manifold 209 rather than the positions to which the nozzles 233a and 233b (see FIG. 1) supply the gases.

### (Eleventh Modification)

Hereinafter, an eleventh modification will be described with reference to FIG. 15D. As shown in FIG. 15D, in the eleventh modification, the nozzle 233d is configured as an L-shaped short nozzle and has its horizontal portion installed to penetrate through the sidewall of the manifold 209 and its vertical portion installed to rise along the inner wall of the manifold 209. Gas supply holes 348e configured to supply the gas are formed in a leading end of the nozzle 233d, and the gas supply holes 348e are opened upward, i.e., in a direction from the manifold 209 toward the reaction tube 203.

Further, in the eleventh modification, in addition to the gas supply holes 348e, a plurality of gas supply holes 348f, for example, are formed in a sidewall of the vertical portion of the nozzle 233d facing the manifold 20). The gas supply holes 348f are configured to be opened toward the inner wall surface of the manifold 209. That is, the gas supply holes 348f are formed opposite to (facing) the inner wall surface of the manifold 209. The nozzle 233d is configured to supply the gas toward an upper portion in the process chamber 201 and the inner wall of the manifold 209, in the manifold 209 rather than the positions to which the nozzles 233a and 233b supply the gases. Further, in the eleventh modification, the nozzle 233d can supply the gas directly toward the inner wall surface of the manifold 209.

### (Twelfth Modification)

Hereinafter, a twelfth modification will be described with reference to FIG. 15E. As shown in FIG. 15E, in the twelfth modification, the nozzle 233d is configured as an L-shaped short nozzle and has its horizontal portion installed to penetrate through the sidewall of the manifold 209 and its vertical portion installed to extend downward along the inner wall of the manifold 209. Gas supply holes 248e configured to supply the gas are formed in a leading end of the nozzle 233d. The gas supply holes 348e are configured to be opened downward, i.e., in a direction from the manifold 209 toward the seal cap 219. That is, the gas supply holes 248e are formed opposite to (facing) the seal cap 219. In the twelfth modification, the nozzle 233d is configured to supply the gas toward a lower portion in the process chamber 201, in the manifold 209 rather than the positions to which the nozzles 233a and 233b (see FIG. 1) supply the gases. Further, the nozzle 233d can supply the gas directly toward the upper surface of the seal cap 219.

### (Thirteenth Modification)

Hereinafter, a thirteenth modification will be described with reference to FIG. 15F. As shown in FIG. 15F, in the thirteenth modification, the nozzle 233d is configured as an L-shaped short nozzle and has its horizontal portion installed to penetrate through the sidewall of the manifold 209 and its vertical portion installed to extend downward along the inner wall of the manifold 209. Gas supply holes 448e configured to supply the gas are formed in a leading end of the nozzle 233d. The gas supply holes 448e are configured to be opened downward, i.e., in a direction from the manifold 209 toward the seal cap 219. That is, the gas supply holes 448e are formed opposite to (facing) the seal cap 219.

Further, in the thirteenth modification, in addition to the gas supply holes 448e, a plurality of gas supply holes 448f, for example, are formed in a sidewall of the vertical portion of the nozzle 233d facing the manifold 209. The gas supply holes 448f are configured to be opened toward the inner wall surface of the manifold 209. That is, the gas supply holes 448f are formed opposite to (facing) the inner wall surface of the manifold 209. The nozzle 233d is configured to supply the gas toward a lower portion in the process chamber 201 and the inner wall of the manifold 209, in the manifold 209 rather than the positions to which the nozzles 233a and 233b supply the gases. The nozzle 233d can supply the gas directly toward the upper surface of the seal cap 219 and also supply the gas directly toward the inner wall surface of the manifold 209.

According to the ninth to thirteenth modifications, it is possible to efficiently remove the deposits including the SiN-free substance containing SiO deposited on the second portion (which may reach a low temperature in the process chamber 201) in particular.

### Additional Embodiments of the Present Disclosure

Hereinabove, the embodiments of the present disclosure have been specifically described, but the present disclosure is not limited to the above-described embodiments and may be variously modified without departing from the spirit of the present disclosure.

For example, while in the above-described embodiments, an example in which the first precursor gas is different in kind from the second precursor gas has been described, the first precursor gas and the second precursor gas may be the same kind. For example, while in the above-described embodiment, an example in which the HCDS gas is used as the first precursor gas and the DCS gas is used as the second precursor gas has been described, the DCS gas may be used as the first precursor gas and the second precursor gas.

In addition, for example, the present disclosure is not limited to the embodiment in which the above-described first and second oxide films are formed by the same film forming method, and they may be formed by different film forming methods from each other.

Further, for example, the NH₃ gas prior supply process may be omitted.

Also, for example, the present disclosure is not limited to the embodiment in which the above-described nitride film is formed by alternately performing the process of supplying the second precursor gas (DCS gas) and the process of supplying the nitriding gas (NH; gas), and the nitride film may be formed by simultaneously performing the process of supplying the second precursor gas and the process of supplying the nitriding gas.

Even in this case, the NH₃ gas prior supply process performed before the second precursor gas and the nitriding gas are simultaneously supplied may be omitted.

Further, although in the above-described embodiments, an example in which the ClF₃ gas is supplied from both the nozzles 233a and 233b has been described, the ClF₃ gas may be supplied only from the nozzle 233a, or the ClF₃ gas may be supplied only from the nozzle 233b. That is, the ClF₃ gas may be supplied from at least any one of the nozzle 233a and the nozzle 233b.

In addition, for example, although in the above-described embodiments, an example in which the stacked film having an SiO/SiN/SiO stack structure (ONO stack structure) is formed has been described, the present disclosure is not limited thereto. For example, the present disclosure may also be appropriately applied to a case in which a stacked film having an SiO/SiN/SiO/SiN/SiO stack structure (ONONO stack structure), a stacked film having an SiN/SiO/SiN stack structure (NON stack structure), a stacked film having an SiO/SiN stack structure (ON stack structure), or a stacked film having an SiN/SiO stack structure (NO stack structure) is formed.

In addition, for example, the film forming sequence of the above-described embodiment is not limited to the case in which the insulating film having the ONO stack structure (or the ONONO, NON, ON, or NO stack structure, or the like) is formed on another film formed on a wafer (i.e., the case in which the stack structure is formed), and the film forming sequence may also be appropriately applied to a case in which the insulating film having the ONO stack structure is formed on a trench structure formed on a surface of a wafer (i.e., a case in which a trench structure is formed).

However, when the stacked film having the ONO, ONONO, NON, ON, or NO stack structure, or the like is formed, if the oxide film is formed on the nitride film, the nitride film, which becomes an underlayer when the oxide film is formed, may be formed to have a thickness larger than the film thickness of the nitride film necessary to constitute the stacked film. That is, when the nitride film, which becomes the underlayer when the oxide film is formed, is formed, the nitride film may be formed to have a film thickness larger than the finally necessary film thickness. When the oxide film is formed on the nitride film according to the film forming sequence of the above-described embodiment and the respective modifications, the surface of the nitride film, which becomes the underlayer in a process of forming the oxide film, is oxidized (consumed), and thus, the film thickness of the nitride film may be smaller than the film thickness of the nitride film necessary to constitute the stacked film, in some cases. In such cases, a film thickness of the nitride film oxidized (consumed) when the oxide film is formed on the nitride film is measured in advance, and the nitride film is formed to be thicker by as much, thereby making it possible to secure the film thickness of the nitride film necessary for the stacked film.

Further, for example, the above-described process of forming the oxide film may also include a process of adding nitrogen (N) into the oxide film. In this case, in the process of forming the oxide film, an additional process of supplying a nitriding gas to the substrate in the process chamber may be provided. In this way, in the process of forming the oxide film, an additional process of adding nitrogen into the oxide film is provided, thereby making it possible to form an oxide film having nitrogen added thereto.

In addition, for example, the above-described process of forming the nitride film may also include a process of adding oxygen (O) into the nitride film. In this case, in the process of forming the nitride film, an additional process of supplying an oxidizing gas to the substrate in the process chamber may be provided. In this way, in the process of forming the nitride film, an additional process of adding oxygen into the nitride film is provided, thereby making it possible to form a nitride film having oxygen added thereto.

Further, for example, although in the above-described embodiment, an example in which a stacked film is formed using a batch type substrate processing apparatus that processes a plurality of substrates at a time has been described, the present disclosure is not limited thereto. The present disclosure may be appropriately applied to a case in which a stacked film is formed using a single-wafer type substrate processing apparatus in which one or several substrates are processed at a time.

Moreover, for example, although in the above-described embodiment, an example in which a stacked film is formed using a substrate processing apparatus having a hot wall type processing furnace has been described, the present disclosure is not limited thereto but may be appropriately applied to a case in which a substrate processing apparatus having a cold wall type processing furnace is used to form a stacked film.

Moreover, the above-described embodiments and modifications may be appropriately combined and used.

In addition, the present disclosure may be implemented by modifying, for example, an existing process recipe or cleaning recipe of the substrate processing apparatus. When the process recipe or cleaning recipe is modified, the process recipe or cleaning recipe according to the present disclosure may be installed to the substrate processing apparatus through an electrical communication line or a recording medium in which the process recipe or cleaning recipe is recorded, or the process recipe or cleaning recipe itself may be changed to the process recipe or cleaning recipe according to the present disclosure by manipulating an input/output device of the substrate processing apparatus.

### Example 1

In Example 1, the process of forming the SiO film on the wafer in the process chamber and the process of forming the SiN film thereon were performed using the same method as the above-described embodiment. Thereafter, in the same manner as the above-described embodiment, the process of supplying the ClF₃ gas into the process chamber and the process of supplying the HF gas into the process chamber were performed to clean the inside of the process chamber.

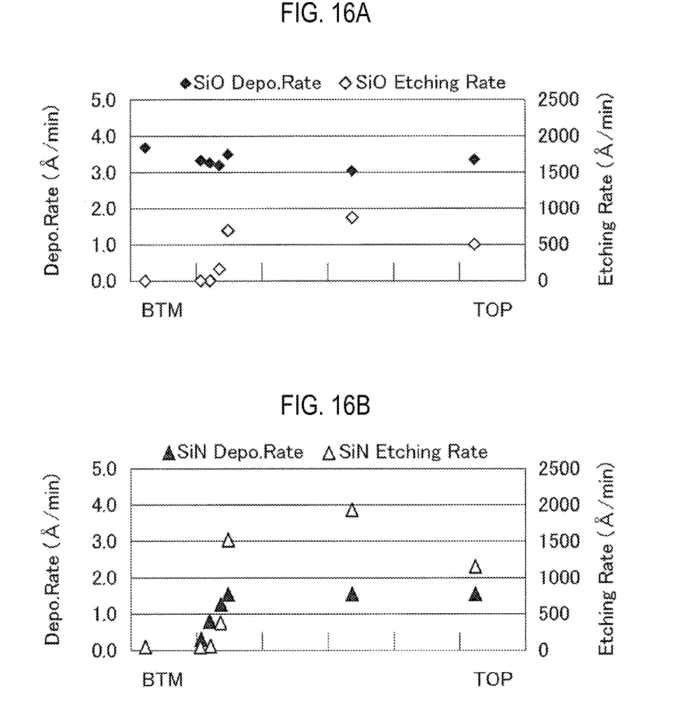

FIG. 16A is a graph showing dependence of a rate at which the SiO film is formed (deposited) (a film forming rate) and a rate at which the SiO film is removed (etched) by the ClF₃ gas (an etching rate) on a position in the reaction tube in Example 1. In FIG. 16A, the horizontal axis represents a position in the reaction tube, where a lower side (bottom side) in the reaction tube is designated at the left side and an upper side (top side) in the reaction tube is designated at the right side. Also, in FIG. 16A, the left vertical axis represents a film forming rate of the SiO film, and the right vertical axis represents an etching rate of the SiO film.

As shown in FIG. 16A, it can be seen that since the film forming rate of the SiO film is not so dependent on the position in the reaction tube, the SiO film is uniformly deposited on the inside of the reaction tube in the vertical direction. It can be seen that when the SiO film is formed on the wafer by the method according to the embodiment, the SiO film also adheres to the lower side, i.e., a relatively low temperature portion in the reaction tube. In the meantime, it can be seen that the etching rate of the SiO film by the ClF₃ gas is largely dependent on the position in the reaction tube, and the etching rate of the SiO film in the lower side in the reaction tube, i.e., the relatively low temperature portion in the reaction tube, is zero, so that the SiO film adhering to the lower side in the reaction tube cannot be removed by the ClF₃ gas. Such a phenomenon is caused by a thermal etching reaction that is hard to occur since the temperature becomes lower at the lower side in the reaction tube and thus reactivity of the ClF₃ gas becomes lower at the lower side in the reaction tube.

FIG. 16B is a graph showing dependence of a rate at which the SiN film is formed (deposited) (a film forming rate) and a rate at which the SiN film is removed (etched) by the ClF₃ gas (an etching rate) on a position in the reaction tube in Example 1. In the same manner as FIG. 16A, in FIG. 16B, the horizontal axis represents a position in the reaction tube, where a lower side (bottom side) in the reaction tube is designated at the left side and an upper side (top side) in the reaction tube is designated at the right side. Also, in FIG. 16B, the left vertical axis represents a film forming rate of the SiN film, and the right vertical axis represents an etching rate of the SiN film.

As shown in FIG. 16B, it can be seen that the film forming rate of the SiN film is largely dependent on the position in the reaction tube and the film forming rate of the SiN film in the lower side in the reaction tube, i.e., the relatively low temperature portion in the reaction tube, is zero, so that the SiN film does not adhere to the low temperature portion of the reaction tube.

In addition, it can be seen that in the same manner as the film forming rate of the SiN film, the etching rate of the SiN film is also largely dependent on the position in the reaction tube. Since the etching rate of the SiN film in neighborhoods of the lower side in the reaction tube is zero, if the SiN film adheres to the neighborhoods of the lower side in the reaction tube, it can be seen that the SiN film cannot be removed by the ClF₃ gas. In addition, it can be understood that the etching rate of the SiN film by the ClF₃ gas in the lower side in the reaction tube, i.e., the relatively low temperature portion in the reaction tube, is slightly smaller as compared with the film forming rate of the SiN film at the same position. Accordingly, although the SiN film can be removed by the ClF₃ gas in the lower side in the reaction tube, the SiN film cannot be sufficiently removed.

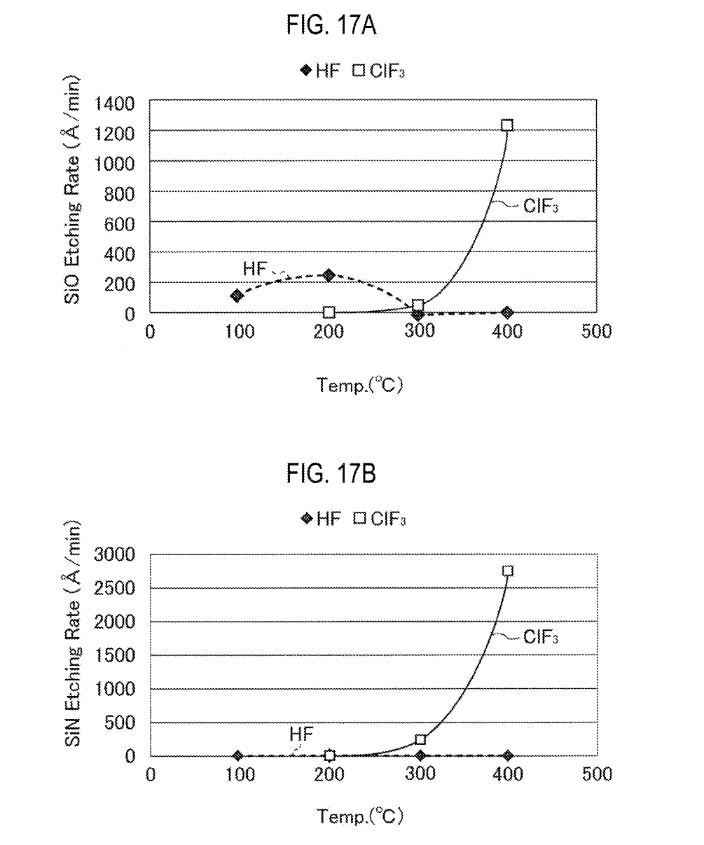

FIG. 17A is a graph showing dependence of a rate at which the SiO film is removed (etched) (an etching rate) on a cleaning gas species in Example 1. The horizontal axis in FIG. 17A represents temperature, and the vertical axis in FIG. 17A represents an etching rate of the SiO film. As shown in FIG. 17A, the dependence of the etching rate of the SiO film on the cleaning gases (HF gas and ClF₃ gas) shows that the etching rate decreases as the temperature decreases when the ClF₃ gas is used, but the etching rate becomes the maximum in the vicinity of 200 degrees C. and the etching rate of the SiO film increases as the temperature decreases when the HF gas is used. Accordingly, it is possible to remove the SiO film on the lower side in the reaction tube by using the reaction of the HF gas at the low temperature.

FIG. 17B is a graph showing dependence of a rate at which the SiN film is removed (an etching rate) on a cleaning gas species. The horizontal axis in FIG. 17B represents temperature, and the vertical axis in FIG. 17B represents an etching rate of the SiN film. As shown in FIG. 17B, it can be seen that the dependence of the etching rate of the SiN film on the cleaning gases (HF gas and ClF₃ gas) shows that the etching rate decreases as the temperature decreases when the ClF₃ gas is used. In addition, it can be seen that it is impossible to remove the SiN film at any temperature range when the HF gas is used.

Hereinabove, as the hydrogen-free fluorine-based gas (ClF₃) is supplied from the first nozzles, which rises from the manifold to the inside of the reaction tube, at least to the inner wall of the reaction tube and the HF gas is supplied from the second nozzle at least to the inner wall of the manifold, the deposits including the stacked film (ONO film) of the SiO and SiN films adhering to the portion, including the inner wall of the reaction tube, which includes the upper side portion in the reaction tube and reaches a relatively high temperature, can be removed by the ClF₃ gas, and the deposits including the SiO film adhering to the portion, including the inner wall of the manifold and the like, which includes the lower side portion in the reaction tube and reaches a relatively low temperature, can be removed by the HF gas, so that the deposits on the portion which may reach a high temperature in the process chamber and the deposits on the portion which may reach a low temperature in the process chamber can simultaneously be removed compatibly.

### Aspects of the Present Disclosure

Hereinafter, some preferred aspects of the present disclosure will be additionally stated.

### (Supplementary Note 1)

According to an aspect of the present disclosure, there is provided a cleaning method for cleaning an inside of a process chamber formed by a reaction tube installed inside a heater and a manifold configured to support the reaction tube and installed under the heater after forming a stacked film of oxide and nitride films on a substrate in the process chamber by alternately performing forming the oxide film and forming the nitride film, the act of forming the oxide film being performed by alternately supplying a first precursor gas to the substrate in the process chamber and supplying an oxygen-containing gas and a hydrogen-containing gas to the substrate in the process chamber under a pressure less than atmospheric pressure once or more, the act of forming the nitride film being performed by alternately supplying a second precursor gas to the substrate in the process chamber and supplying a nitrogen-containing gas to the substrate in the process chamber once or more, including: supplying a hydrogen-free fluorine-based gas from a first nozzle at least to an inner wall of the reaction tube, the first nozzle being installed in the manifold and raised from the manifold to an inside of the reaction tube, and supplying a hydrogen fluoride gas from a second nozzle at least to an inner wall of the manifold, the second nozzle being installed in the manifold.

### (Supplementary Note 2)

In the cleaning method according to Supplementary Note 1, in the act of supplying the hydrogen-free fluorine-based gas, a first deposit including the stacked film of the oxide and nitride films adhering to a first portion including the inner wall of the reaction tube (at least the inner wall of the reaction tube) is removed, and in the act of supplying the hydrogen fluoride gas, a second deposit including the oxide film adhering to a second portion including the inner wall of the manifold (at least the inner wall of the manifold) is removed, the second portion having a lower temperature than the first portion when the stacked film is formed

### (Supplementary Note 3)

In the cleaning method according to Supplementary Note 1 or 2, the act of supplying the hydrogen-free fluorine-based gas and the act of supplying the hydrogen fluoride gas are simultaneously performed.

### (Supplementary Note 4)

In the cleaning method according to Supplementary Note 3, the act of supplying the hydrogen fluoride gas is initiated prior to the act of supplying the hydrogen-free fluorine-based gas.

### (Supplementary Note 5)

In the cleaning method according to Supplementary Note 3, the act of supplying the hydrogen-free fluorine-based gas is initiated prior to the act of supplying the hydrogen fluoride gas.

### (Supplementary Note 6)

In the cleaning method according to any one of Supplementary Notes 3 to 5, the act of supplying the hydrogen-free fluorine-based gas is terminated prior to terminating the act of supplying the hydrogen fluoride gas.

### (Supplementary Note 7)

In the cleaning method according to any one of Supplementary Notes 3 to 5, the act of supplying the hydrogen fluoride gas is terminated prior to terminating the act of supplying the hydrogen-free fluorine-based gas.

### (Supplementary Note 8)

In the cleaning method according to any one of Supplementary Notes 3 to 5, when the inside of the process chamber is cleaned, while an internal temperature of the reaction tube is set to a first temperature, the act of supplying the hydrogen-free fluorine-based gas and the act of supplying the hydrogen fluoride gas are simultaneously performed, and thereafter, while the internal temperature of the reaction tube is set to a second temperature lower than the first temperature, the act of supplying the hydrogen fluoride gas is solely performed.

### (Supplementary Note 9)

In the cleaning method according to Supplementary Note 1 or 2, when the inside of the process chamber is cleaned, the act of supplying the hydrogen-free fluorine-based gas and the act of supplying the hydrogen fluoride gas are simultaneously performed, and a cycle is performed a predetermined number of times, the cycle including sealing the hydrogen-free fluorine-based gas and the hydrogen fluoride gas in the process chamber, maintaining the state of the hydrogen-free fluorine-based gas and the hydrogen fluoride gas sealed in the process chamber, and exhausting the inside of the process chamber.

### (Supplementary Note 10)

In the cleaning method according to Supplementary Note 1 or 2, when the inside of the process chamber is cleaned, the act of supplying the hydrogen-free fluorine-based gas and the act of supplying the hydrogen fluoride gas are alternately performed.

### (Supplementary Note 11)

In the cleaning method according to any one of Supplementary Notes 1 to 3, when the inside of the process chamber is cleaned, in the act of supplying the hydrogen-free fluorine-based gas, the hydrogen-free fluorine-based gas is intermittently supplied, and in the act of supplying the hydrogen fluoride gas, the hydrogen fluoride gas is intermittently supplied.

### (Supplementary Note 12)

In the cleaning method according to any one of Supplementary Notes 1 to 3, when the inside of the process chamber is cleaned, in the act of supplying the hydrogen-free fluorine-based gas, the hydrogen-free fluorine-based gas is continuously supplied, and in the act of supplying the hydrogen fluoride gas, the hydrogen fluoride gas is intermittently supplied.

### (Supplementary Note 13)

In the cleaning method according to any one of Supplementary Notes 1 to 3, when the inside of the process chamber is cleaned, in the act of supplying the hydrogen-free fluorine-based gas, the hydrogen-free fluorine-based gas is intermittently supplied, and in the act of supplying the hydrogen fluoride gas, the hydrogen fluoride gas is continuously supplied.

### (Supplementary Note 14)

According to another aspect of the present disclosure, there is provided a method of manufacturing a semiconductor device, including: forming a stacked film of oxide and nitride films on a substrate in a process chamber formed by a reaction tube installed inside a heater and a manifold configured to support the reaction tube and installed under the heater by alternately performing forming the oxide film and forming the nitride film, the act of forming the oxide film being performed by alternately supplying a first precursor gas to the substrate in the process chamber and supplying an oxygen-containing gas and a hydrogen-containing gas to the substrate in the process chamber under a pressure less than atmospheric pressure once or more, the act of forming the nitride film being performed by alternately supplying a second precursor gas to the substrate in the process chamber and supplying a nitrogen-containing gas to the substrate in the process chamber once or more; and cleaning an inside of the process chamber after the act of forming the stacked film, the act of cleaning the inside of the process chamber, including: supplying a hydrogen-free fluorine-based gas from a first nozzle at least to an inner wall of the reaction tube, the first nozzle being installed in the manifold to extend upward from the manifold to an inside of the reaction tube; and supplying a hydrogen fluoride gas from a second nozzle at least to an inner wall of the manifold, the second nozzle being installed in the manifold.

### (Supplementary Note 15)

According to still another aspect of the present disclosure, there is provided a substrate processing apparatus, including: a process chamber formed by a reaction tube installed inside a heater and a manifold configured to support the reaction tube and installed under the heater; a gas supply system configured to supply gas into the process chamber; a first nozzle installed in the manifold to extend upward from the manifold to an inside of the reaction tube; a second nozzle installed in the manifold; a pressure adjusting part configured to adjust an internal pressure of the process chamber; and a control part configured to control the heater, the gas supply system and the pressure adjusting part so as to perform; forming a stacked film of oxide and nitride films on a substrate in the process chamber by alternately performing forming the oxide film and forming the nitride film, the act of forming the oxide film being performed by alternately supplying a first precursor gas to the substrate in the process chamber and supplying an oxygen-containing gas and a hydrogen-containing gas to the substrate in the process chamber under a pressure less than atmospheric pressure once or more, the act of forming the nitride film being performed by alternately supplying a second precursor gas to the substrate in the process chamber and supplying a nitrogen-containing gas to the substrate in the process chamber once or more; and cleaning an inside of the process chamber after the act of forming the stacked film is performed, the act of cleaning the inside of the process chamber including supplying a hydrogen-free fluorine-based gas from the first nozzle at least to an inner wall of the reaction tube, and supplying a hydrogen fluoride gas from the second nozzle at least to an inner wall of the manifold.

### (Supplementary Note 16)

According to still another aspect of the present disclosure, there are provided a program and a non-transitory computer-readable recording medium storing the program, the program causing a computer to perform a process of forming a stacked film of oxide and nitride films on a substrate in a process chamber formed by a reaction tube installed inside a heater and a manifold configured to support the reaction tube and installed under the heater by alternately performing forming the oxide film and forming the nitride film, the act of forming the oxide film being performed by alternately supplying a first precursor gas to the substrate in the process chamber and supplying an oxygen-containing gas and a hydrogen-containing gas to the substrate in the process chamber under a pressure less than atmospheric pressure once or more, the act of forming the nitride film being performed by alternately supplying a second precursor gas to the substrate in the process chamber and supplying a nitrogen-containing gas to the substrate in the process chamber once or more; and a process of cleaning an inside of the process chamber after forming the stacked film, the process of cleaning the inside of the process chamber, including: supplying a hydrogen-free fluorine-based gas from a first nozzle at least to an inner wall of the reaction tube, the first nozzle being installed in the manifold to extend upward from the manifold to an inside of the reaction tube; and supplying a hydrogen fluoride gas from a second nozzle at least to an inner wall of the manifold, the second nozzle being installed in the manifold.

According to the present disclosure, it is possible to provide a cleaning method, which may uniformly and simultaneously remove deposits on a portion which may reach a high temperature in the process vessel and deposits on a portion which may reach a low temperature in the process vessel compatibly.

As described above, the present disclosure may be applied to a cleaning method, which includes a process of forming a thin film on a substrate, a method of manufacturing a semiconductor device, a substrate processing apparatus and a recording medium.

While certain embodiments have been described, these embodiments have been presented by way of example only, and are not intended to limit the scope of the disclosures. Indeed, the novel methods and apparatuses described herein may be embodied in a variety of other forms; furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A cleaning method for cleaning an inside of a process chamber formed by a reaction tube installed inside a heater and a manifold configured to support the reaction tube and installed under the heater, alter forming a stacked film of oxide and nitride films on a substrate in the process chamber by alternately performing forming the oxide film and forming the nitride film, the act of forming the oxide film being performed by alternately supplying a first precursor gas to the substrate in the process chamber and supplying an oxygen-containing gas and a hydrogen-containing gas to the substrate in the process chamber under a pressure less than atmospheric pressure once or more, the act of forming the nitride film being performed by alternately supplying a second precursor gas to the substrate in the process chamber and supplying a nitrogen-containing gas to the substrate in the process chamber once or more, comprising:
supplying a hydrogen-free fluorine-based gas from a first nozzle at least to an inner wall of the reaction tube, the first nozzle being installed in the manifold to extend upward from the manifold to an inside of the reaction tube; and
supplying a hydrogen fluoride gas from a second nozzle at least to an inner wall of the manifold, the second nozzle being installed in the manifold.

2. The cleaning method of claim 1, wherein
in the act of supplying the hydrogen-free fluorine-based gas, a first deposit including the stacked film of the oxide and nitride films adhering to a first portion including the inner wall of the reaction tube is removed, and
in the act of supplying the hydrogen fluoride gas, a second deposit including the oxide film adhering to a second portion including the inner wall of the manifold is removed, the second portion having a lower temperature than the first portion when the stacked film is formed.

3. The cleaning method of claim 1, wherein the act of supplying the hydrogen-free fluorine-based gas and the act of supplying the hydrogen fluoride gas are simultaneously performed.

4. The cleaning method of claim 3, wherein the act of supplying the hydrogen fluoride gas is initiated prior to the act of supplying the hydrogen-free fluorine-based gas.

5. The cleaning method of claim 3, wherein the act of supplying the hydrogen-free fluorine-based gas is initiated prior to the act of supplying the hydrogen fluoride gas.

6. The cleaning method of claim 3, wherein the act of supplying the hydrogen-free fluorine-based gas is terminated prior to terminating the act of supplying the hydrogen fluoride gas.

7. The cleaning method of claim 3, wherein the act of supplying the hydrogen fluoride gas is terminated prior to terminating the act of supplying the hydrogen-free fluorine-based gas.

8. The cleaning method of claim 3, wherein when the inside of the process chamber is cleaned,
while an internal temperature of the reaction tube is set to a first temperature, the act of supplying the hydrogen-free fluorine-based gas and the act of supplying the hydrogen fluoride gas are simultaneously performed, and
thereafter, while the internal temperature of the reaction tube is set to a second temperature lower than the first temperature, the act of supplying the hydrogen fluoride gas is solely performed.

9. The cleaning method of claim 1, wherein when the inside of the process chamber is cleaned,
the act of supplying the hydrogen-free fluorine-based gas and the act of supplying the hydrogen fluoride gas are simultaneously performed, and a cycle is performed a predetermined number of times, the cycle including sealing the hydrogen-free fluorine-based gas and the hydrogen fluoride gas in the process chamber, maintaining the state of the hydrogen-free fluorine-based gas and the hydrogen fluoride gas sealed in the process chamber, and exhausting the inside of the process chamber.

10. The cleaning method of claim 1, wherein when the inside of the process chamber is cleaned,
the act of supplying the hydrogen-free fluorine-based gas and the act of supplying the hydrogen fluoride gas are alternately performed.

11. The cleaning method of claim 1, wherein when the inside of the process chamber is cleaned,
in the act of supplying the hydrogen-free fluorine-based gas, the hydrogen-free fluorine-based gas is intermittently supplied, and
in the act of supplying the hydrogen fluoride gas, the hydrogen fluoride gas is intermittently supplied.

12. The cleaning method of claim 1, wherein when the inside of the process chamber is cleaned,
in the act of supplying the hydrogen-free fluorine-based gas, the hydrogen-free fluorine-based gas is continuously supplied, and
in the act of supplying the hydrogen fluoride gas, the hydrogen fluoride gas is intermittently supplied.

13. The cleaning method of claim 1, wherein when the inside of the process chamber is cleaned,
in the act of supplying the hydrogen-free fluorine-based gas, the hydrogen-free fluorine-based gas is intermittently supplied, and
in the act of supplying the hydrogen fluoride gas, the hydrogen fluoride gas is continuously supplied.

14. A method of manufacturing a semiconductor device, comprising:
forming a stacked film of oxide and nitride films on a substrate in a process chamber formed by a reaction tube installed inside a heater and a manifold configured to support the reaction tube and installed under the heater by alternately performing forming the oxide film and forming the nitride film, the act of forming the oxide film being performed by alternately supplying a first precursor gas to the substrate in the process chamber and supplying an oxygen-containing gas and a hydrogen-containing gas to the substrate in the process chamber under a pressure less than atmospheric pressure once or more, the act of forming the nitride film being performed by alternately supplying a second precursor gas to the substrate in the process chamber and supplying a nitrogen-containing gas to the substrate in the process chamber once or more; and
cleaning an inside of the process chamber after the act of forming the stacked film,
the act of cleaning the inside of the process chamber, comprising:
supplying a hydrogen-free fluorine-based gas from a first nozzle at least to an inner wall of the reaction tube, the first nozzle being installed in the manifold to extend upward from the manifold to an inside of the reaction tube; and
supplying a hydrogen fluoride gas from a second nozzle at least to an inner wall of the manifold, the second nozzle being installed in the manifold.

15. A substrate processing apparatus, comprising:
a process chamber formed by a reaction tube installed inside a heater and a manifold configured to support the reaction tube and installed under the heater;
a gas supply system configured to supply gas into the process chamber;
a first nozzle installed in the manifold to extend upward from the manifold to an inside of the reaction tube;
a second nozzle installed in the manifold;
a pressure adjusting part configured to adjust an internal pressure of the process chamber; and
a control part configured to control the heater, the gas supply system and the pressure adjusting part so as to perform: forming a stacked film of oxide and nitride films on a substrate in the process chamber by alternately performing forming the oxide film and forming the nitride film, the act of forming the oxide film being performed by alternately supplying a first precursor gas to the substrate in the process chamber and supplying an oxygen-containing gas and a hydrogen-containing gas to the substrate in the process chamber under a pressure less than atmospheric pressure once or more, the act of forming the nitride film being performed by alternately supplying a second precursor gas to the substrate in the process chamber and supplying a nitrogen-containing gas to the substrate in the process chamber once or more; and cleaning an inside of the process chamber after the act of forming the stacked film is performed, the act of cleaning the inside of the process chamber comprising supplying a hydrogen-free fluorine-based gas from the first nozzle at least to an inner wall of the reaction tube, and supplying a hydrogen fluoride gas from the second nozzle at least to an inner wall of the manifold.

16. A non-transitory computer-readable recording medium storing a program that causes a computer to perform a process of forming a stacked film of oxide and nitride films on a substrate in a process chamber formed by a reaction tube installed inside a heater and a manifold configured to support the reaction tube and installed under the heater by alternately performing forming the oxide film and forming the nitride film, the act of forming the oxide film being performed by alternately supplying a first precursor gas to the substrate in the process chamber and supplying an oxygen-containing gas and a hydrogen-containing gas to the substrate in the process chamber under a pressure less than atmospheric pressure once or more, the act of forming the nitride film being performed by alternately supplying a second precursor gas to the substrate in the process chamber and supplying a nitrogen-containing gas to the substrate in the process chamber once or more; and a process of cleaning an inside of the process chamber after forming the stacked film,
the process of cleaning the inside of the process chamber, comprising:
supplying a hydrogen-free fluorine-based gas from a first nozzle at least to an inner wall of the reaction tube, the first nozzle being installed in the manifold to extend upward from the manifold to an inside of the reaction tube; and
supplying a hydrogen fluoride gas from a second nozzle at least to an inner wall of the manifold, the second nozzle being installed in the manifold.
